(19) United States
(12) Patent Application Publication
(10) Pub. No.: US 2006/0231868 A1
(43) Pub. Date: Oct. 19, 2006

(54) Semiconductor device for high voltage IC

(75) Inventors: Akira Yamada, Nukata-gun (JP); Hiroaki Himi, Nagoya-city (JP); Nozomu Akagi, Nukata-gun (JP); Junichi Nagata, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/405,399

(22) Filed: Apr. 18, 2006

(30) Foreign Application Priority Data
Apr. 19, 2005 (JP) 2005-121306
Nov. 1, 2005 (JP) 2005-318679

(51) Int. Cl. H01L 29/768

(52) U.S. Cl. 257/239

(57) ABSTRACT

A semiconductor device includes: a plurality of transistors connected in series between a ground potential and a predetermined potential; an input terminal provided by a gate terminal of the first step transistor; a plurality of resistors connected in series between the ground potential and the predetermined potential; and an output terminal provided by a predetermined potential side terminal of the Nth step transistor. A gate terminal of each transistor other than the first step transistor is sequentially connected between neighboring two resistors. One of the resistors defined as an Ith step resistor has a resistance, which is smaller than a resistance of a (I+1)th step resistor.

### CROSS REFERENCE TO RELATED APPLICATIONS

This application is based on Japanese Patent Applications No. 2005-121306 filed on Apr. 19, 2005, and No. 2005-318679 filed on Nov. 1, 2005, the disclosures of which are incorporated herein by reference.

### FIELD OF THE INVENTION

The present invention relates to a semiconductor device for a high voltage IC.

### BACKGROUND OF THE INVENTION

High voltage ICs for driving inverters and the like have been disclosed in, for instance, Japanese Patent No. 3384399 (which corresponds to U.S. Pat. No. 5,736,774), and Proceedings of ISPSD '04, pages 375-378, H. Akiyama et al. by Mitsubishi Electric Company.

FIG. 22A is a circuit arrangement diagram for showing a power portion of a motor controlling inverter which is disclosed in U.S. Pat. No. 5,736,774. Power devices (namely, IGBTs Q1 to Q6, and diodes D1 to D6) employed so as to drive a three-phase motor Mo constitute a bridge circuit, and are constructed in the structure of a power module stored in the same package. A main power supply “V_{CC}” is normally DC 100V to 400 V, namely a high voltage. More specifically, in automobile-purpose motor control operations for electric vehicles (EVs), hybrid vehicles (HEVS) and the like, the main power supplies V_{CC} become DC 650 V, namely a high DC voltage. In the case that a high potential side of the main power supply V_{CC} is expressed as “V_{CCH}” and a low potential side thereof is expressed as “V_{CCL}”, in order to drive the IGBTs Q1 to Q3 connected to V_{CCH}, potentials of gate electrodes of these IGBTs Q1 to Q3 become higher than this high potential V_{CCH}. As a result, either PC (photocoupler) or a high voltage IC (HVIC: High Voltage Integrated Circuit) 90 is employed in a drive circuit. An input/output (I/O) of the drive circuit is normally connected to a microcomputer, so that the entire portion of the inverter is controlled by this microcomputer.

FIG. 22B is a block diagram for indicating an internal structural unit of a high voltage IC (HVIC) which is employed in FIG. 22A.

The high voltage IC 90 shown in FIG. 22B is arranged by a control circuit (CU: Control Unit), gate drive circuits (GDUS: Gate Drive Units) 4 to 6, gate drive circuits GDU 1 to 3, and a level shift circuit (LSU: Level Shift Unit). The gate drive circuits GDUs 4 to 6 use a GND potential having a low potential as a reference potential. The gate drive circuits GDUs 1 to 3 use a floating potential having a high potential as a reference potential. The control circuit CU transmits/receives signals via the input/output terminal I/O with respect to the microcomputer, and produces such control signals which turn on any of these IGBs Q1 to Q6, and turn off any of these IGBs Q1 to Q6 shown in FIG. 22A. The gate drive circuits GDUs 4 to 6 drive the IGBTs Q4 to Q6, which are connected to the low potential side V_{CCL} of the main power supply V_{CC} shown in FIG. 22A. The gate drive circuits GDUs 1 to 3 drive the IGBTs Q1 to Q3, which are connected to the high potential side V_{CCH} of the main power supply V_{CC} shown in FIG. 22A. The level shift circuit LSU functions as an intermediary between a signal having the V_{CCL} level of the control circuit CU, and signals (SIN 1 to 3, SOUT 1 to 3) of the GDUs 1 to 3, whose levels are shifted between the V_{CCH} level and the V_{CCL} level. As a consequence, as previously explained, since the semiconductor device which constitutes the level shift circuit LSU of the high voltage IC 90 handles the signals having the levels between the V_{CCH} level and the V_{CCL} level (namely, 0 V to 650 V), a high withstanding voltage (approximately 1200 V) is especially required for this semiconductor device.

In general, in a semiconductor device where two, or more circuits having different reference potentials have been integrated such as the high voltage IC 90 shown in FIG. 22B, forming regions of the respective circuits having the different reference potentials are separated from each other by a dielectric isolation with employment of either a PN junction isolation or a dielectric substance such as SiO₂. In general, as to a high voltage IC using a PN junction isolation, since a stray transistor is easily formed, there are some possibilities that a circuit is erroneously operated and element destruction may be induced. To the contrary, in a high voltage IC using a dielectric isolation, a stray transistor operation does not occur, but also, there are no such problems that the circuit is erroneously operated, and the element is destroyed.

Further, in order to realize a high withstanding semiconductor device by employing an SOI structural semiconductor substrate, both concentration and a thickness of an SOI layer, and a thickness of an embedded oxide film must be designed in optimum dimensions in such a manner that an applied voltage is distributed to the SOI layer and the embedded oxide film so as to obtain a desirable withstanding voltage along the longitudinal direction of the sectional plane thereof.

However, when a high withstanding voltage higher than, or equal to 1000 V is tried to be obtained by executing this method, it is required to manufacture an embedded oxide film having a thickness thicker than 5 μm and an SOI layer having a thickness thicker than 50 μm. On the other hand, due to a relative matter of a camber, or the like of the SOI substrate, an upper limited film thickness of an achievable embedded oxide film is on the order of 4 μm. Also, normally, a thickness of an SOI layer is approximately several μm to 20 μm. If the thickness of the SOI layer is increased, then a trench processing load is increased. As a consequence, in the MOS type transistor Tr_{L} formed in a level shift circuit forming region, there is such a limitation that a withstanding voltage of approximately 600 V is secured. Accordingly, such a withstanding voltage of 1200 V which is required in a 400 V power supply system and EV vehicles cannot be secured.

Furthermore, it is required to provide a semiconductor device capable of securing an arbitrary necessary withstanding voltage, and also capable of avoiding circuit destruction not only even under stationary condition, but also even in such a case that surge is entered to the semiconductor device. Further, it is required to provide such a semiconductor device capable of avoiding circuit destruction and of securing a sufficiently high switching speed even when a large voltage dividing resistance is added to the semiconductor device.

### SUMMARY OF THE INVENTION

In view of the above-described problem, it is an object of the present invention to provide a semiconductor device having a sufficient withstanding voltage and/or a sufficient high switching speed.

A semiconductor device includes: a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two; an input terminal provided by a gate terminal of the first step transistor; a plurality of resistors, which are connected in series between the ground potential and the predetermined potential, wherein one of the resistors disposed on the utmost ground potential side is defined as a first step resistor, and another resistor disposed on the utmost predetermined potential side is defined as a Nth step resistor; and an output terminal provided by a predetermined potential side terminal of the Nth step transistor. A gate terminal of each transistor other than the first step transistor is sequentially connected between neighboring two resistors. One of the resistors defined as an Ith step resistor has a resistance, which is smaller than a resistance of a (I+1)th step resistor, and I is a given natural number in a range between one and (N-1).

In the above device, when the input signal is inputted into the gate terminal of the first transistor, the second to the Nth transistors can be operated simultaneously through N resistors, which are connected in series between the GND potential and the predetermined potential. When the device is operated under a normal condition, the voltage between the GND potential and the predetermined potential is divided by N transistors so that each voltage range is distributed in each transistor. Accordingly, the withstand voltage of each transistor, which is required for each transistor, is reduced, compared with a case where only one transistor covers the voltage between the GND potential and the predetermined potential. Thus, even when each transistor has a conventional withstand voltage, the device has high withstand voltage as a whole.

Further, when each resistor has the same high resistance, the charge of the surge current is accommodated in the resistor, which is disposed far from the power source of the predetermined potential, so that the surge current cannot be discharged to the GND side. Accordingly, a high voltage is applied to the transistor disposed far from the power source, so that the transistor may be broken, and the total circuit may be destroyed. However, in the above device, the resistance of the resistor becomes smaller, as the arrangement of the resistor departs from the power source. Thus, the charge of the surge current can be discharged to the GND side rapidly. Therefore, high voltage is not applied to the transistor disposed far from the power source, so that breakdown of the transistor is restricted, and breakdown of the whole circuit is also restricted.

Thus, the above device has high withstand voltage totally, which is required for the device, and circuit breakdown of the device is limited even when a voltage surge is inputted into the device.

Further, a semiconductor device includes: a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two; an input terminal provided by a gate terminal of the first step transistor; a plurality of resistors, which are connected in series between the ground potential and the predetermined potential, wherein one of the resistors disposed on the utmost ground potential side is defined as a first step resistor, and another resistor disposed on the utmost predetermined potential side is defined as a Nth step resistor; an output terminal provided by a predetermined potential side terminal of the Nth step transistor; and a plurality of first capacitors. A gate terminal of each transistor other than the first step transistor is sequentially connected between neighboring two resistors, and each first capacitor is connected in parallel to each transistor.

In the above device, since the voltage between the. GND potential and the predetermined potential is divided by N transistors, the required withstand voltage of each transistor is substantially reduced to one-Nth. Accordingly, the device has high withstand voltage as a whole.

Further, the first capacitor is connected in parallel to each transistor. N transistors are connected in series between the GND potential and the predetermined potential. Accordingly, the first capacitor connected in parallel to each transistor is substantially connected in series between the GND potential and the predetermined potential. Thus, a transmission passage of an alternating current is formed between the GND potential and the predetermined potential.

When the device is switched on or off, the transmission passage composed of the first capacitor functions as a bypass passage of the input signal pulse for transmitting a potential of the pulse. Specifically, when the input signal pulse starts to rise or when the input signal pulse starts to decay, the gate capacitor of each transistor can be charged up or discharged through the bypass passage. Accordingly, when the input signal pulse starts to rise or when the input signal pulse starts to decay, the signal change is rapidly transmitted to each transistor through the bypass passage. Thus, the device has an additional passage for charge and discharge of the gate capacitance so that a switching speed of the device is improved. Here, in a case where the device does not have the first capacitor connected in parallel to each transistor, the current flows into each transistor through a load resistor when the input signal pulse is inputted into the device. A potential drop of each transistor is transmitted so that an output signal is retrieved from the device. Thus, a delay caused by the on-state resistance of each transistor and each load resistor is generated so that a switching speed of the device may be reduced.

Furthermore, when the voltage surge is applied to the device, the charge of the surge current is rapidly discharged to the GND side through the transmission passage provided by the first capacitor. Accordingly, high voltage caused by the voltage surge is not applied to each transistor, so that circuit breakdown of the device is prevented.

Further, even when the device has a parasitic capacitance therein, the circuit breakdown of the device is restricted when the voltage surge is applied to the device. Specifically, by designing the capacitance of the first capacitor to be larger than the parasitic capacitance, the charge of the surge current is rapidly discharged to the GND side through the transmission passage of the alternating component, and the potential drop caused by the parasitic capacitance is cancelled so that the voltage applied to each transistor is equalized. Thus, the circuit breakdown caused by breakdown of the transistor is limited.

Thus, the above device has high withstand voltage totally, which is required for the device, and circuit breakdown of the device is limited even when a voltage surge is inputted into the device. Further, even when the above device has the parasitic capacitance, the circuit breakdown of the device is limited. Furthermore, even when a high voltage dividing resistance is added into the device, the device has sufficient switching speed.

Furthermore, a semiconductor device includes: a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two; an input terminal provided by a gate terminal of the first step transistor; a plurality of parallel RC elements, which are connected in series between the ground potential and the predetermined potential, wherein each parallel RC element includes a resistor and a second capacitor, which are connected in parallel each other, and wherein one of the parallel RC elements disposed on the utmost ground potential side is defined as a first step parallel RC element, and another parallel RC element disposed on the utmost predetermined potential side is defined as a Nth step parallel RC element; and an output terminal provided by a predetermined potential side terminal of the Nth step transistor. A gate terminal of each transistor other than the first step transistor is sequentially connected between neighboring two parallel RC elements.

In the above device, since the voltage between the GND potential and the predetermined potential is divided by N transistors, the required withstand voltage of each transistor is substantially reduced to one-Nth. Accordingly, the device has high withstand voltage as a whole.

In the above device, a transmission passage provided by the second capacitor functions as a bypass passage of the input signal pulse for transmitting a potential of the pulse. Accordingly, when the input signal pulse starts to rise or when the input signal pulse starts to decay, the signal change is rapidly transmitted to each transistor through the bypass passage. Thus, the device has an additional passage for chare and discharge of the gate capacitance so that a switching speed of the device is improved.

Further, when the voltage surge is applied to the device, the charge of the surge current is rapidly discharged to the GND side through the transmission passage. Accordingly, high voltage caused by the voltage surge is not applied to each transistor, so that circuit breakdown of the device is prevented.

Furthermore, even when the device has a parasitic capacitance therein, the circuit breakdown of the device is restricted when the voltage surge is applied to the device. Specifically, by designing the capacitance of the second capacitor to be larger than the parasitic capacitance, the charge of the surge current is rapidly discharged to the GND side through the transmission passage of the alternating component, and the potential drop caused by the parasitic capacitance is cancelled so that the voltage applied to each transistor is equalized. Thus, the circuit breakdown caused by breakdown of the transistor is limited.

Thus, the above device has high withstand voltage totally, which is required for the device, and circuit breakdown of the device is limited even when a voltage surge is inputted into the device. Further, even when the above device has the parasitic capacitance, the circuit breakdown of the device is limited. Furthermore, even when a high voltage dividing resistance is added into the device, the device has sufficient switching speed.

### BRIEF DESCRIPTION OF THE DRAWINGS

The above and other objects, features and advantages of the present invention will become more apparent from the following detailed description made with reference to the accompanying drawings. In the drawings:

FIG. 1 is a circuit diagram showing an equivalent circuit of a semiconductor device according to a first embodiment of the present invention;

FIG. 2 is a graph showing a resistance of each resistor in the device shown in FIG. 1;

FIG. 3 is a graph showing a simulation result of a dV/dt surge in the device shown in FIG. 1;

FIG. 4 is a circuit diagram showing an equivalent circuit of a semiconductor device according to a second embodiment of the present invention;

FIG. 5 is a graph showing a capacitance of each second capacitor in the device shown in FIG. 4;

FIG. 6 is a graph showing a simulation result of a dV/dt surge in the device shown in FIG. 4;

FIG. 7 is a graph showing a relationship between a dose amount and a sheet resistance in a poly silicon film;

FIG. 8A is a plan view showing a second capacitor having a dielectric layer in an insulation separation trench, and FIG. 8B is a cross sectional view showing the second capacitor taken along line VIIIB-VIIIB in FIG. 8A;

FIG. 9 is a graph showing a relationship between a circumferential length of all cells and a capacitance in the second capacitor in FIG. 8A;

FIGS. 10A to 10D are circuit diagrams showing an equivalent circuit of each semiconductor device according to modifications of the first or the second embodiment of the present invention;

FIG. 11 is a circuit diagram showing an equivalent circuit of a semiconductor device similar to the device in FIG. 10D according to another modification of the first or the second embodiment of the present invention;

FIG. 12 is a graph showing a simulation result of a dV/dt surge in the device shown in FIG. 11;

FIG. 13 is a circuit diagram showing an equivalent circuit of a semiconductor device similar to the device in FIG. 10B according to another modification of the first or the second embodiment of the present invention;

FIG. 14 is a graph showing a simulation result of a response to a pulse signal input in the device shown in FIG. 13;

FIG. 15 is a circuit diagram showing an equivalent circuit of a semiconductor device similar to the device in FIG. 10C according to another modification of the first or the second embodiment of the present invention;

FIG. 16 is a graph showing a simulation result of a response to a pulse signal input in the device shown in FIG. 15;

FIG. 17A is a graph showing an experimental result of a response to a pulse signal input in another semiconductor device similar to the device shown in FIG. 10B, and FIG. 17B is a graph showing an experimental result of a response to a pulse signal input in another semiconductor device similar to the device shown in FIG. 10C;

FIG. 18 is a cross sectional view showing a capacitor used for the first or the second capacitor in the device according to the first or the second embodiment;

FIG. 19 is a cross sectional view showing another capacitor used for the first or the second capacitor in the device according to the first or the second embodiment;

FIG. 20 is a cross sectional view showing further another capacitor used for the first or the second capacitor in the device according to the first or the second embodiment;

FIG. 21 is a cross sectional view showing furthermore another capacitor used for the first or the second capacitor in the device according to the first or the second embodiment;

FIG. 22A is a circuit diagram showing a power portion in an inverter for controlling a motor, according to a prior art, and FIG. 22B is a block diagram showing a high voltage IC in the inverter in FIG. 22A;

FIG. 23 is a cross sectional view showing another high voltage IC having a SOI substrate and a separation trench, according to the prior art;

FIG. 24 is a circuit diagram showing an equivalent circuit of a semiconductor device according to a related art;

FIG. 25 is a plan view showing a high voltage IC having the semiconductor device in FIG. 24;

FIG. 26 is a plan view showing a level shift circuit and a floating reference gate driving circuit in the high voltage IC in FIG. 25;

FIG. 27 is a cross sectional view showing the level shift circuit and the floating reference gate driving circuit taken along line XXVII-XXVII in FIG. 26;

FIG. 28 is a cross sectional view showing the level shift circuit and the floating reference gate driving circuit taken along line XXVIII-XXVIII in FIG. 26;

FIG. 29 is a circuit diagram showing an equivalent circuit of a semiconductor device according to a comparison of the first embodiment of the present invention;

FIG. 30 is a graph showing a simulation result of a dV/dt surge in the device shown in FIG. 29;

FIG. 31 is a circuit diagram showing an equivalent circuit of another semiconductor device according to the comparison of the first embodiment of the present invention;

FIG. 32 is a graph showing a simulation result of a dV/dt surge in the device shown in FIG. 31;

FIG. 33 is a circuit diagram showing an equivalent circuit of further another semiconductor device according to the comparison of the first embodiment of the present invention;

FIG. 34 is a graph showing a simulation result of a response to a pulse signal input in the device shown in FIG. 33;

FIG. 35 is a circuit diagram showing an equivalent circuit of a semiconductor device according to another modification of the first embodiment of the present invention; and

FIG. 36 is a circuit diagram showing an equivalent circuit of a semiconductor device according to further another modification of the first embodiment of the present invention.

### DETAILED DESCRIPTION OF THE PREFERRED EMBODIMENTS

In inventors have preliminarily studied about a semiconductor device for a high voltage IC.

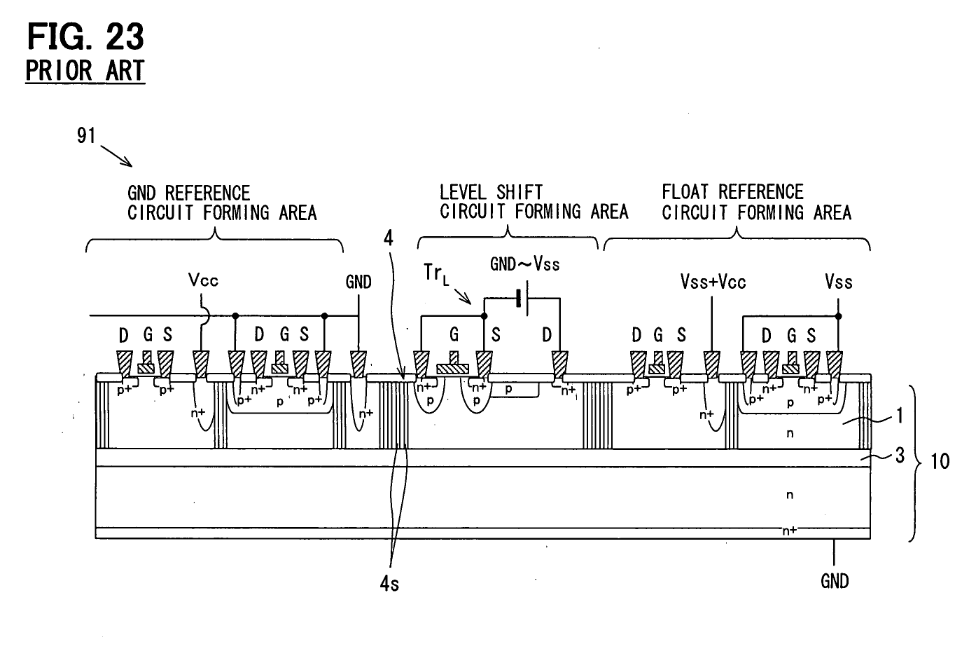

FIG. 23 is a sectional view for schematically showing a conventional high voltage IC 91 with employment of an SOI substrate and a trench isolation.

In the high voltage IC 91 shown in FIG. 23, a low potential (GND) reference circuit, a high potential (floating potential) reference circuit, and a level shift circuit are provided on an SOI layer 1 of an SOI substrate 10 having an embedded oxide film 3. The respective forming regions as to the GND reference circuit, the floating reference circuit, and the level shift circuit are insulated (dielectric) and isolated by the embedded oxide film 3 of the SOI substrate 10 and a side wall oxide film 4s of a trench 4.

In the level shift circuit of the high voltage IC 91, a circuit element having a high withstanding voltage is required so as to couple the low potential reference circuit with the high potential reference circuit. A MOS type transistor Tr_{L} of the level shift circuit forming region shown in FIG. 23 employs a so-called “SOI-RESURF structure” in order to secure a withstanding voltage.

As indicated in this drawing, a high voltage of the level shift circuit is applied to a drain (D) of the MOS type transistor Tr_{L}. In this MOS type transistor Tr_{L} of FIG. 23, a withstanding voltage of a sectional plane of this transistor along a lateral direction is secured by the SOI-RESURF structure constituted by both a surface P type impurity layer and the embedded oxide film 3. Also, as to a withstanding voltage of the sectional plane of this transistor along a longitudinal direction, the high voltage applied between the drain (D) and the ground (GND) is subdivided by the SOI layer 1 having the low concentration and the embedded oxide film 3 so as to relax the electric field in the SOI layer 1. This operation is described in, for example, Proceedings of ISPSD '04, pages 375-378, H. Akiyama et al. by Mitsubishi Electric Company.

As previously explained, in order to realize a high withstanding semiconductor device by employing an SOI structural semiconductor substrate, both concentration and a thickness of an SOI layer, and a thickness of an embedded oxide film must be designed in optimum dimensions in such a manner that an applied voltage is distributed to the SOI layer and the embedded oxide film so as to obtain a desirable withstanding voltage along the longitudinal direction of the sectional plane thereof.

However, when a high withstanding voltage higher than, or equal to 1000 V is tried to be obtained by executing this method, it is required to manufacture an embedded oxide film having a thickness thicker than 5 μm and an SOI layer having a thickness thicker than 50 μm . On the other hand, due to a relative matter of a camber, or the like of the SOI substrate, an upper limited film thickness of an achievable embedded oxide film is on the order of 4 μm . Also, normally, a thickness of an SOI layer is approximately several μm to 20 μm. If the thickness of the SOI layer is increased, then a trench processing load is increased. As a consequence, in the MOS type transistor Tr_{L} formed in the level shift circuit forming region of FIG. 23, there is such a limitation that a withstanding voltage of approximately 600 V is secured. Accordingly, such a withstanding voltage of 1200 V which is required in a 400 V power supply system and EV vehicles cannot be secured.

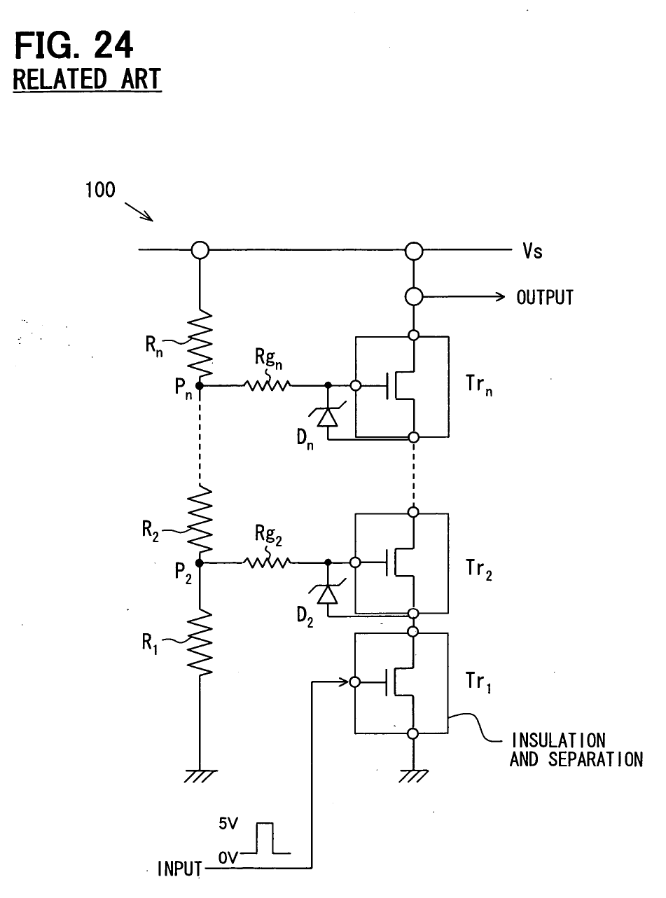

To solve the above-explained problem, the Inventors of the present patent application could invent a novel semiconductor device 100 as represented in FIG. 24.

FIG. 24 is a basic equivalent circuit diagram as to the above-explained semiconductor device 100.

In the semiconductor device 100 shown in FIG. 24, “n” pieces (n≧2) of transistor elements “Tr₁” to “Trₙ” which are insulated and isolated from each other are successively connected in a series connecting manner between a ground (GND) potential and a predetermined potential Vs under such a condition that a transistor element on the GND potential side is defined as a first stage of these transistor elements Tr₁ to Trₙ, and a transistor element on the predetermined potential (Vs) side is defined as an n-th stage thereof. It should be understood that “n” pieces of these transistor elements Tr₁ to Trₙ may be realized by MOS (Metal Oxide Semiconductor) type transistor elements, or IGBT (Insulated Gate Bipolar Transistor) elements. Assuming now that the respective transistor elements Tr₁ to Trₙ correspond to the MOS type transistor elements in the above-described circuit arrangement, a drain voltage of a MOS type transistor element provided at the lower stage is applied to a source of a MOS type transistor element provided at the upper stage.

Also, “n” pieces of resistance element “R₁” to “Rₙ” are sequentially connected in a series connection manner between the same GND potential and the same predetermined potential Vs in such a manner that the GND-sided resistance element is a first stage of these resistance elements R₁ to Rₙ and the predetermined potential (Vs)-sided resistance element is an n-th stage thereof. While a very small current flows through these “n” pieces of the resistance elements R₁ to Rₙ, a voltage between the GND potential and the predetermined potential Vs is subdivided by the respective resistance elements R₁ to Rₙ. Although the voltage between the GND potential and the predetermined potential Vs is subdivided by the respective resistance elements R₁ to Rₙ in FIG. 24, this voltage may be alternatively subdivided by employing capacitance elements. In this alternative case, there is a merit that current consumption may be reduced.

In the semiconductor device 100 of FIG. 24, gate terminals of the transistor elements Tr₂ to Trₙ provided at the respective stages except for the transistor element Tr₁ provided at the first stage are sequentially connected via resistance elements “Rg₂” to “Rgₙ” to junction points “P₂” to “Pₙ.” These junction points “P₂” to “Pₙ” are present among the resistance elements R₁ to Rₙ of the respective stages which are series-connected to each other. Also, in the transistor elements Tr₂ to Trₙ of the respective stages except for the transistor element Tr₁ of the first stage, diodes “D₂” to “Dₙ” are interposed between the gate elements and terminals on the GND potential side. Since these resistance elements Rg₂ to Rgₙ and these diodes D₂ to Dₙ are employed, when an input signal is applied to the gate terminal of the transistor element Trₙ of the first stage, simultaneous operations as to the transistor elements Tr₂ to Trₙ of the second stage to the n-th stage can be stabilized.

The gate terminal of the transistor element Tr₁ of the first stage constitutes an input terminal of the semiconductor device 100. An output signal of the semiconductor device 100 is derived via a load resistor (not shown) having a predetermined resistance value from the terminal on the predetermined potential (Vs) side of the transistor element Trₙ of the n-th stage. It should also be noted that the output signal is derived under such a condition that the reference potential is level-shifted from the GND potential of the input signal to the predetermined potential Vs, and is inverted with respect to the input signal.

In the semiconductor device 100 of FIG. 24, since the input signal is applied to the gate terminal of the transistor element Tr₁ of the first stage, the transistor elements Tr₂ to Trₙ from the second stage to the n-th stage can be simultaneously operated via “n” pieces of the resistance elements R₁ to Rₙ which are similarly series-connected between the GND potential and the predetermined potential Vs. In other words, while the respective transistor elements Tr₂ to Trₙ are constructed of MOS type transistor elements, if the GND potential sides of the respective transistor elements Tr₁ to Trₙ are used as sources, then a drain potential of the transistor element Tr₁ of the first stage is lowered when a signal voltage is applied to the gate terminal of the transistor element Tr₁ of the first stage. In conjunction with this operation, since a source potential of the transistor element Tr₂ of the second stage is lowered, a current may flow from the junction point P₂ into the diode D₂ between the gate terminal and the source of the transistor element Tr₂ of the second stage. As a result of such a fact that the voltage between the gate terminal and the source is fixed to a zener voltage (5 V in this circuit), the transistor element Tr₂ of the second stage is turned on. A similar operation is repeatedly carried out up to the transistor Trₙ of the n-th stage, so that all of the transistor elements TR₁ to Trₙ are turned on within a very short time.

In operations of the semiconductor device 100 of FIG. 24, a voltage between the GND potential and the predetermined potential Vs is subdivided by “n” pieces of these transistor elements Tr₁ to Trₙ, and thus, the respective transistor elements Tr₁ to Trₙ from the first stage to the n-th stage share respective voltage ranges. As a consequence, withstanding voltages required for the respective transistor elements Tr₁ to Trₙ become nearly equal to 1/n, as compared with such a withstanding voltage case that the voltage between the GND potential and the predetermined potential Vs is shared by a single transistor element. As a result, these transistor elements can be manufactured in low cost by employing a general-purpose manufacturing method, and even if transistor elements having normal withstanding voltages are employed, properly selected numbers of these transistor elements are series-connected to each other, so that such a semiconductor device capable of securing a required high withstanding voltage can be realized as the semiconductor device 100 of FIG. 24. It should also be understood that in the semiconductor device 100 of FIG. 24, it is preferable that “n⇄ pieces of these transistors Tr₁ to Trₙ own the same withstanding voltages. Accordingly, the voltages (withstanding voltages) shared by the respective transistor elements Tr₁ to Trₙ interposed between the GND potential and the predetermined potential (Vs) can be made equal to each other and can be minimized.

Concretely speaking, for instance, while a general-purpose SOI substrate containing an embedded oxide film a thickness of 2 μm is employed, a MOS type transistor element having a withstanding voltage of 150 V can be easily manufactured by employing a general-purpose manufacturing method. As a consequence, “n” pieces of transistor elements Tr₁ to Trₙ which are insulated and isolated from each other by the insulating/isolating trenches are formed on the above-described SOI substrate, and are connected to each other in a series connection manner, which constitute the semiconductor device 100 made of the “n” stages of transistor elements, so that a semiconductor device having a high withstanding voltage can be realized. For instance, since a transistor element having a withstanding voltage of 150 V is series-connected to each other in 2 stages, 4 stages, and 8 stages as shown in FIG. 24, semiconductor devices 100 having a withstanding voltage of 300 V, a withstanding voltage of 600 V, and a withstanding voltage of 1200 V can be manufactured respectively. Accordingly, there is no necessity to change the wafer structure (SOI layer), the thickness of the embedded oxide film, and the impurity concentration of the SOI layer in response to withstanding voltages. Also, such a high withstanding voltage semiconductor device can be readily realized even under such a condition that a processing depth of an insulating/isolating trench is constant, and a required withstanding voltage is higher than, or equal to 1000 V.

As previously explained, the semiconductor device 100 shown in FIG. 24 can secure the arbitrary necessary withstanding voltage and may be manufactured as such a semiconductor device manufacturable in the low cost by using the general-purpose manufacturing method for the semiconductor device.

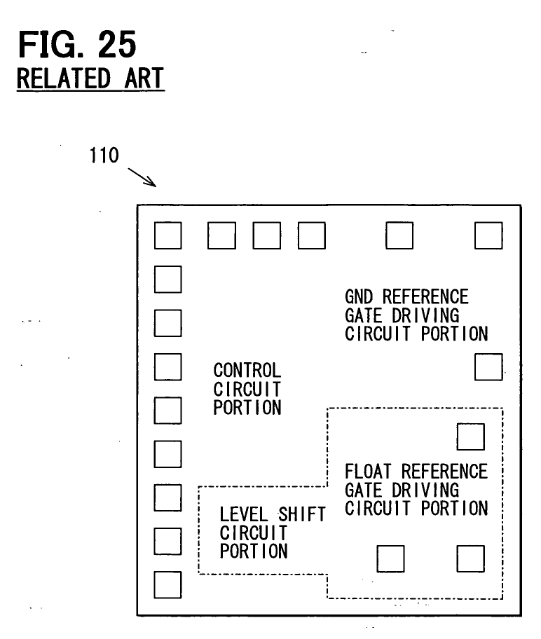

FIG. 25 is a plan view for schematically showing a high voltage IC 110 to which the semiconductor device 100 shown in the basic equivalent circuit diagram of FIG. 24 has been applied.

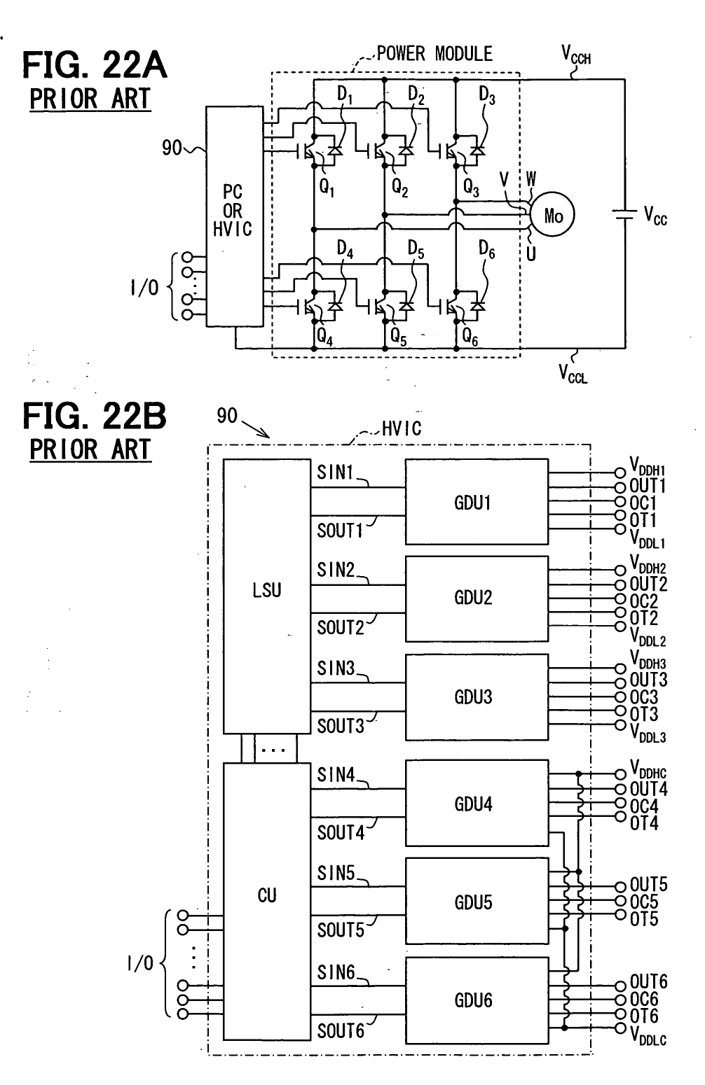

The high voltage IC 110 of FIG. 25 corresponds to an inverter driving-purpose high voltage IC which is similar to the high voltage IC 90 explained with reference to FIG. 22. The high voltage IC 110 shown in FIG. 25 is arranged by a GND reference gate driving circuit using a GND potential as a reference; a floating reference gate driving circuit using a floating potential as a reference; a control circuit for controlling the GND reference gate driving circuit and the floating reference gate driving circuit; and a level shift circuit. This level shift circuit is interposed between the control circuit and the floating reference gate driving circuit, and shifts a level of an input/output signal of the control circuit between the GND potential and the floating potential. The semiconductor device 100 shown in FIG. 24 is applied to the level shift circuit provided in the high voltage IC 110 of FIG. 25. In this case, the predetermined potential Vs of FIG. 24 is defined as a positive floating potential of approximately 1200 V.

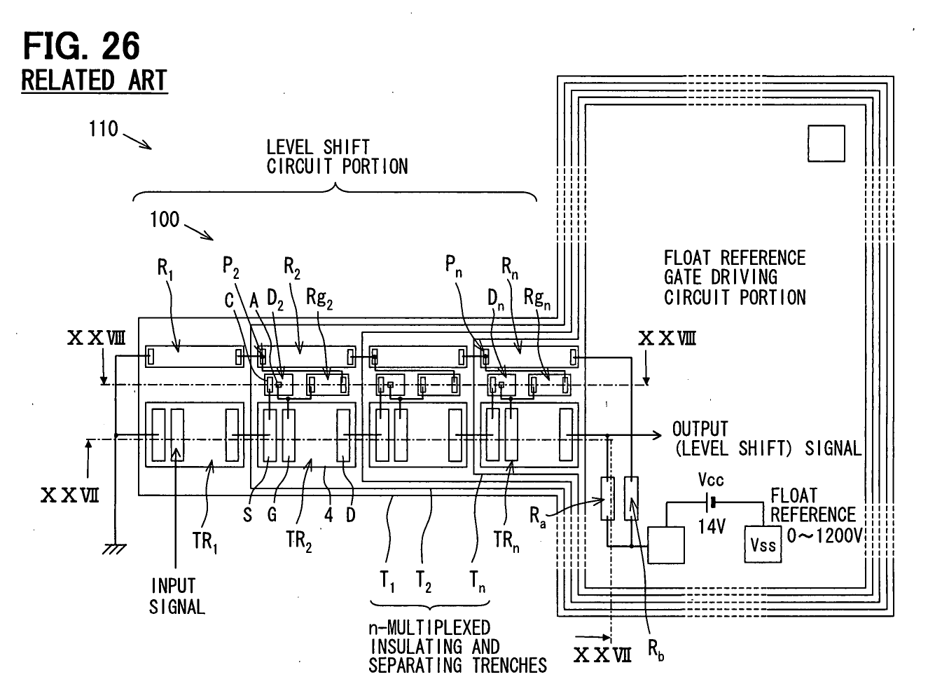

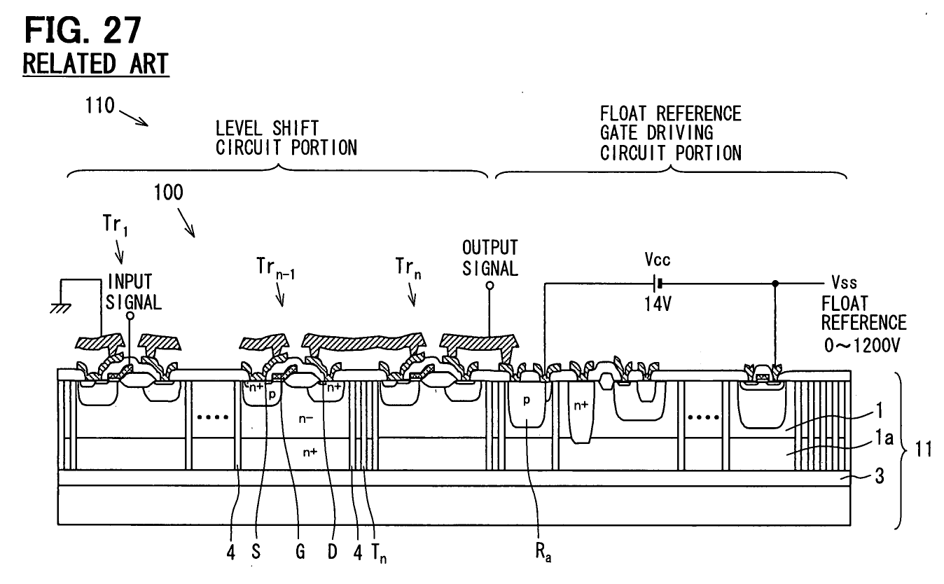

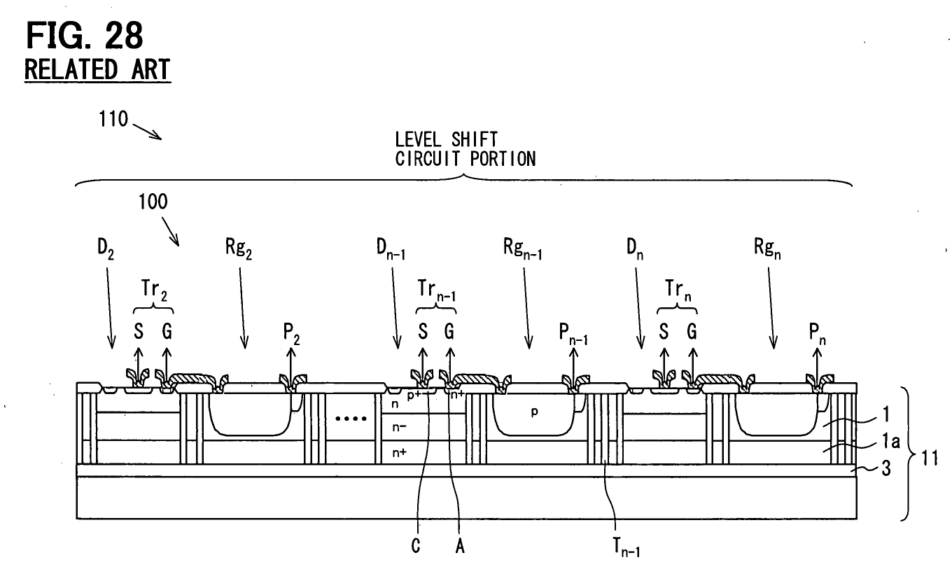

FIG. 26 is a diagram for indicating a level shift circuit unit and a floating reference gate driving circuit unit in detail, which are surrounded by a dot/dash line, in the high voltage IC 110 of FIG. 25. Normally, FIG. 26 is a circuit for indicating an arrangement of respective circuit elements of the semiconductor device 100 of FIG. 24, which are applied to the level shift circuit. FIG. 27 is a sectional view of the above-described circuit units, taken along a dot/dash line XXVII-XXVII of FIG. 26, and indicates structures of the respective transistor elements. Also, FIG. 28 is a sectional view of the circuit units, taken along a dot/dash line XXVIII-XXVIII of FIG. 26, and shows structures of diodes and resistance elements connected to gates of the respective transistor elements.

As indicated in the sectional view of FIG. 27, in the high voltage IC 110, “n” pieces of the transistor elements Tr₁ to Trₙ employed in the semiconductor device 100 of FIG. 24 which are applied to the level shift circuit are formed in an “N” conductivity type SOI layer 1 of an SOI structure semiconductor substrate 11 having an embedded oxide film 3. These “n” pieces of transistor elements Tr₁ to Trₙ are LDMOS (Lateral Double-diffused MOS) type transistor elements which are insulated and isolated from each other by insulating/isolating trenches 4 which are reached to the embedded oxide film 3.

As shown in the sectional view of FIG. 28, in the high voltage IC 110, “P” conductive type diffused resistors are employed as resistor elements “Rg₂” to “Rgₙ.” In the respective resistor elements “Rg₂” to “Rgₙ”, the SOI layer 1 is fixed at the same potential on the high potential side so as to suppress an adverse influence of a potential. When “N” conductivity type diffused resistors are employed, the SOI layer 1 must be fixed at the same potential on the low potential side. It should also be noted that as the resistance elements RG₂ to Rgₙ and the resistance elements R₁ to Rₙ, bulk resistors having high resistance values, thin-film polysilicon resistive members, and thin-film CrSi resistors may be alternatively employed in addition to the diffused resistors.

Also, an indicated in FIG. 26, in the semiconductor device 100 of the high voltage IC 110, “n”-multiple of insulating/isolating trenches T₁ to Tₙ are formed which are reached to the embedded oxide film 3, and “n” pieces of transistor elements “Tr₁” to “Trₙ” which are insulated/isolated from each other are sequentially arranged one by one on the respective regions surrounded by the “n”-multiple of insulating/isolating trenches T₁ to Tₙ in such a manner that these transistor elements Tr₁ to Trₙ include transistor elements of high stages. As a result, in response to a voltage increase from the GND potential up to the predetermined potential, voltages applied to the respective regions which are surrounded by “n”-multiple of the insulating/isolating trenches T₁ to Tₙ can be made equal to each other, and the voltage ranges shared by “n” pieces of the transistor elements Tr₁ to Trₙ can be sequentially moved from the GND potential to the predetermined potential. It should also be noted that since only one set of “n”-multiple of the insulating/isolating trenches T₁ to Tₙ is present between the adjoining transistor elements, the connecting/wiring operation of “n” pieces of the transistor elements Tr₁ to Trₙ can be easily carried out, and the occupied area can be reduced, so that the semiconductor device 100 can be made compact.

As previously explained, in the semiconductor device 100, “n” pieces of the transistor elements Tr₁ to Trₙ may be realized by such transistor elements having normal withstanding voltages. Also, in order to increase the withstanding voltage, the impurity concentration of the SOI layer 1 need not be especially selected to low concentration. As a result, as shown in FIG. 27 and FIG. 28, different from the high voltage IC 91 of FIG. 23, such a high concentration impurity layer la having higher concentration than the impurity concentration of the SOI layer 1 and having the same conductivity type as that of this SOI layer 1 may be formed on the embedded oxide film 3 in the SOI layer 1. As a result, even when a voltage noise is produced which is steeply changed around the semiconductor device 100, an extension of a depletion layer from the embedded oxide film 3 may be suppressed. As a consequence, such a semiconductor device whose erroneous operation caused by the voltage noise has been suppressed can be manufactured. For example, an adverse influence can be shielded which is caused by interference of high frequency potentials. The high frequency potential interference is induced by a dV/dt variation occurred in connection with switching operations within the floating reference gate driving circuit of the output stage.

As previously explained, the high voltage ICs 110 shown in FIG. 25 to FIG. 28 can secure the withstanding voltage of 1200 V, and thus, can constitute such high voltage ICS suitably used so as to drive inverters of on-vehicle motors, and to drive inverters of on-vehicle air conditioners. It should also be understood that the above-described inventive idea has already been filed as Japanese Patent Applications No. 2004-308724 and No. 2005-227058, which are filed by the present inventors and correspond to U.S. patent application Ser. No. 11/253,678. On the other hand, while the semiconductor device 100 shown in FIG. 24 is applied to the level shift circuit unit of the high voltage IC 110, a characteristic in the case that dV/dt surge is entered is simulated. As a result, the below-mentioned problem is revealed.

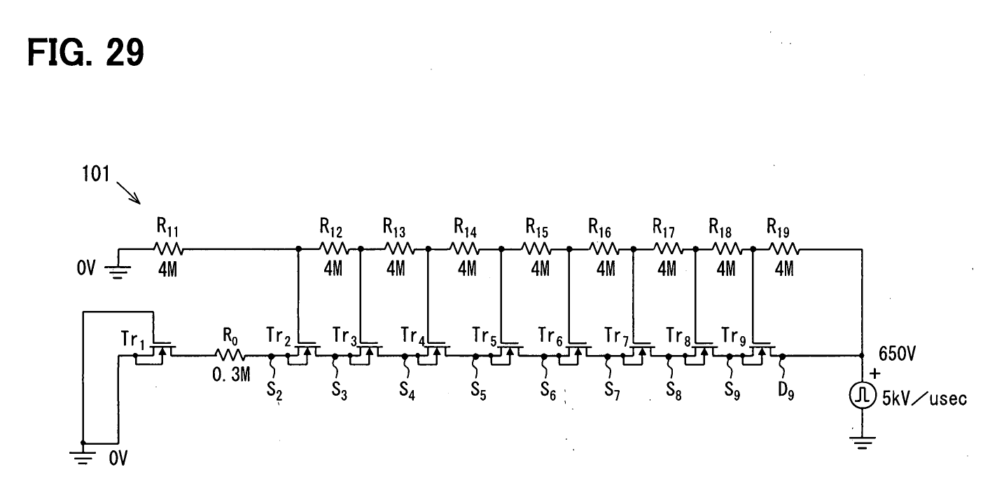

FIG. 29 is an equivalent circuit diagram of a semiconductor device 101 as a comparison, which was employed in the above-explained simulation.

As shown in FIG. 29, in the semiconductor device 101, transistors “Tr₁” to “Tr₉” constructed of 9 pieces of LDMOSs are sequentially series-connected to each other between the GND potential (0 V) and a power supply potential of 650 V corresponding to the predetermined potential Vs. Also, 9 pieces of resistance elements “R₁₁” to “R₁₉” are sequentially series-connected to each other between the same GND potential of 0 V and the same power supply potential of 650 V. Resistance values of these 9 resistance elements R₁₁ to R₁₉ are completely equal to each other, and are set to 4 MΩ. It should also be noted that a resistance element “R₀” having a resistance value of 0.3 MΩ is inserted in order to adjust a current flowing through the transistor elements Tr₁ to Tr₉.

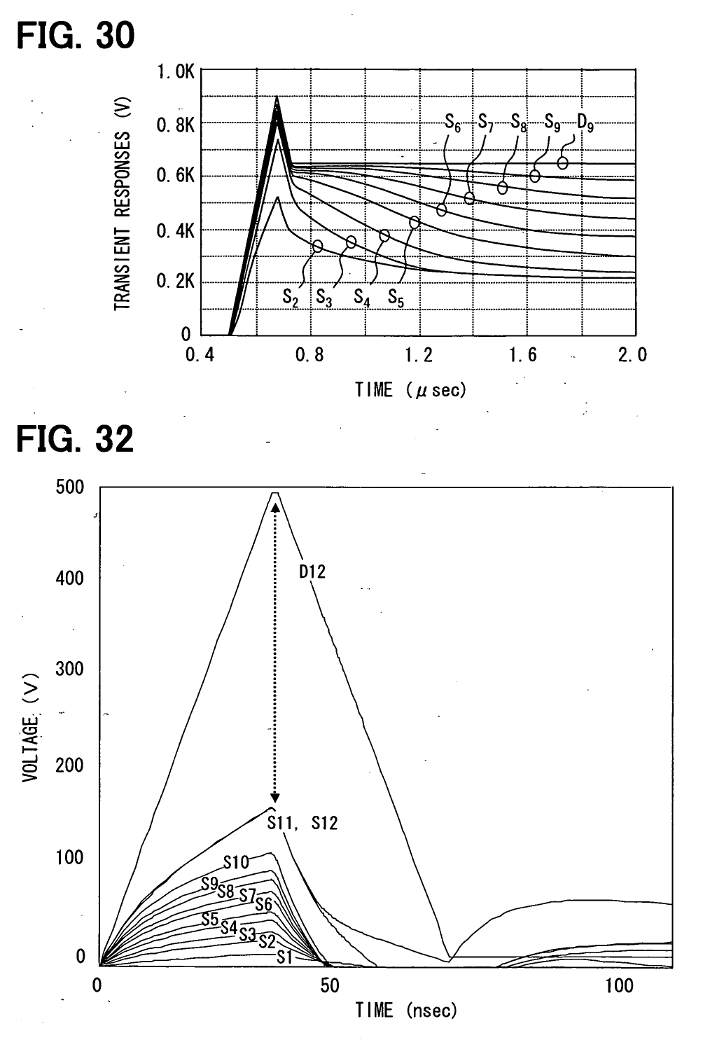

FIG. 30 represents a simulation result of the semiconductor device 101 in such a case that dV/dt surge of 5 KV/sec is inputted. Respective graphs indicated by symbols S2 to S9 and D9 in this drawing show potentials at the respective points denoted in FIG. 29, and denote source potentials of the transistor elements Tr₂ to Tr₉ and a drain potential of the transistor element Tr₉, respectively.

In the semiconductor device 101 under stationary state, the power supply voltage of 650 V can be equally subdivided by 9 pieces of these transistor elements Tr₁ to Tr₉. On the other hand, as shown in FIG. 30, when the dV/dt surge of 5 kV/μsec is entered, the potential at the point S2 is instantaneously increased at a time instant when the surge is entered, and such a potential difference which is higher than, or equal to a half of the power supply voltage is applied to the first-staged transistor element Tr₁. As a result, this first-staged transistor element Tr1 is brought into a break down state, so that the circuit is destroyed.

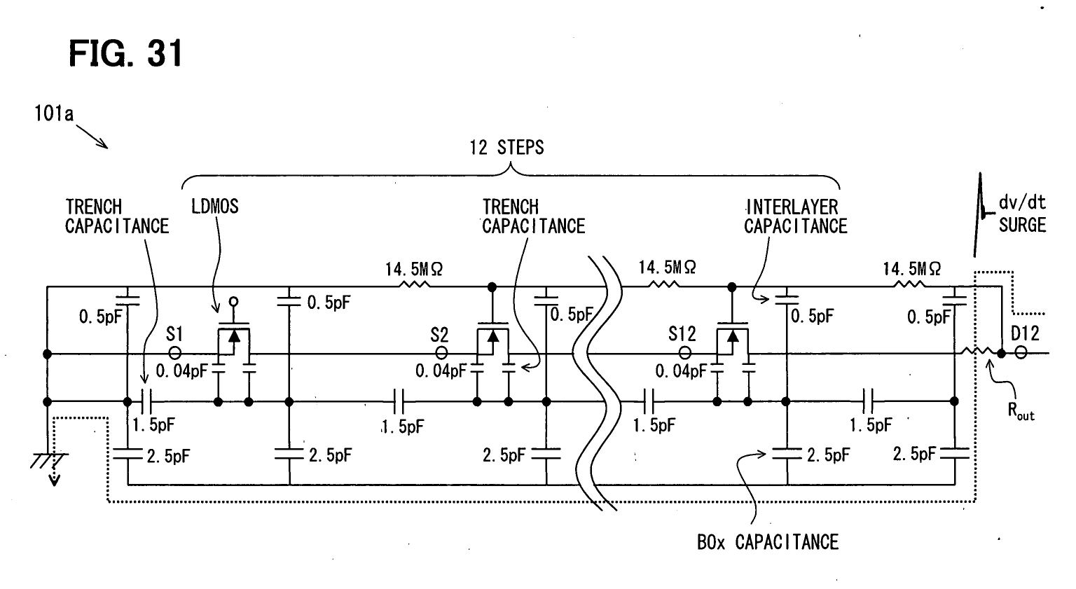

FIG. 31 and FIG. 32 show simulation results of another semiconductor device 101a.

FIG. 31 is an equivalent circuit diagram of the semiconductor device 101a employed in the simulation. FIG. 32 shows a simulation result of the semiconductor device 101a in the case that dV/dt surge is entered. FIG. 32 represents a graph for representing changes in a time elapse in potentials at the respective points S1 to S12 on the source sides of the LDMOSs in the respective stages shown in FIG. 31, and a potential at a point D12 of an output resistor Rₒᵤₜ on the power supply side, which is equal to the potential of the dV/dt surge.

As shown in FIG. 31, in the semiconductor device 101a, transistor elements constructed of 12 pieces of LDMOSs are sequentially series-connected to each other between the GND potential and a predetermined power supply potential. Also, 12 pieces of resistance elements each having a resistance value of 14.5 MΩ are sequentially series-connected to each other between the same GND potential and the same power supply potential. It should also be understood that in the simulation of the semiconductor device 101a shown in FIG. 31, different from the simulation of the semiconductor device 101 shown in FIG. 29, stray capacitances of an embedded oxide film (BOx), a trench, an interlayer film, which are produced in the respective portions of the SOI substrate are considered.

As indicated in FIG. 32, in the case that the dV/dt surge is inputted to the semiconductor device 101a of FIG. 31 which considers the stray capacitances, a large potential difference is produced between the points S12 and D12. This potential difference is higher than, or equal to ½ of the power supply voltage, and is denoted by a wide dot line having arrows at both ends in FIG. 32. As a result, a high voltage is applied to the 12th-staged transistor element located at the nearest position with respect to the power supply, and the output resistor Rₒᵤₜ, and thus, either the 12th-staged transistor element or the output resistor Rₒᵤₜ are brought into a break down condition, so that the circuit is destroyed. It should be noted that the source S11 of the 11th-staged LDMOS and the source S12 of the 12th-staged LDMOS become the same potentials, and no voltage is applied to both terminals of the 12th-staged LDMOS in FIG. 32. However, this is caused by the circuit arrangement shown in FIG. 31, and does not constitute an essential matter.

The occurrence factor as to the large potential difference which is shown by the dot line having the arrows in FIG. 32 may be conceived as follows: That is, since the resistance value of the voltage dividing resistors series-connected to each other as shown in FIG. 31 is large, namely, 14.5 MΩ, flowing of the dV/dt surge current into the voltage dividing resistors is restricted, the dV/dt surge current flows via the stray capacitances into the substrate side, as represented by a wide dot line having arrows in FIG. 31. As a result, a voltage applied to a specific element is increased, so that the withstanding voltage is eventually decreased.

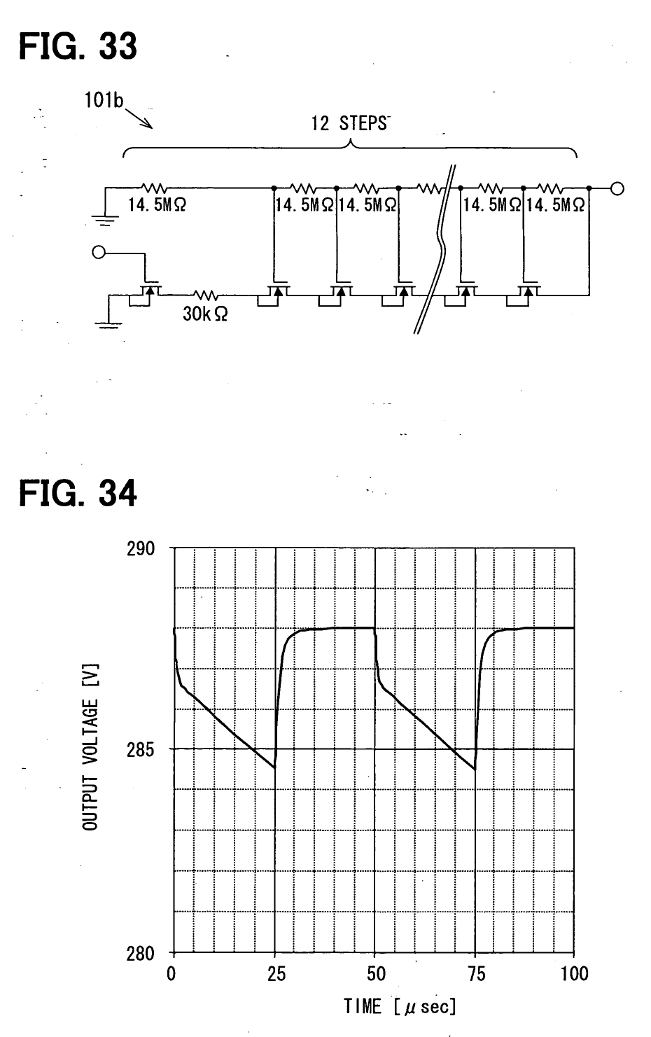

FIG. 33 and FIG. 34 indicate simulation results as to another semiconductor device 101b.

FIG. 33 is an equivalent circuit diagram of the semiconductor device 101b employed in the simulation. FIG. 34 shows a simulation result for representing a response characteristic of the semiconductor device 101b with respect to a pulse signal input, namely represents a falling characteristic of an output potential from the power supply potential with respect to the pulse signal input. As previously explained, in the semiconductor device 101b, an output signal thereof is derived under such a condition that the reference potential is level-shifted from the GND potential of the input signal to the predetermined potential, and then, the output signal is inverted with respect to the positive input signal.

As shown in FIG. 33, in the semiconductor device 101b, transistor elements constructed of 12 pieces of LDMOSs are sequentially series-connected to each other between the GND potential and a predetermined power supply potential. Also, 12 pieces of resistance elements each having a resistance value of 14.5 MΩ are sequentially series-connected to each other between the same GND potential and the same power supply potential.

In the graph of FIG. 34, as seen from a response between 50 μ sec and 75 μ sec, in this semiconductor device 101b, a falling characteristic of an output signal when an input signal is entered becomes dull. This reason is conceivable as follows: That is, the resistance value of the voltage dividing resistors employed in the semiconductor device 101b of FIG. 33 is large, namely 14.5 MΩ. In other words, since the high resistance is added to the gates of LDMOSs at the respective stages and the drain thereof at the input stage, when a pulse signal is entered to the input terminal of the semiconductor device 101b, a current flows through the load resistor R_{O} to the sources/drains of the respective LDMOSs, so that a potential drop is transferred. As a result, delays are produced by the load resistor R_{O} and the ON resistors of the respective LDMOSs, so that a switching speed of the entire device made of a collected member of LDMOSs becomes slow.

Thus, it is required to provide a semiconductor device capable of securing an arbitrary necessary withstanding voltage, and also capable of avoiding circuit destruction not only even under stationary condition, but also even in such a case that surge is entered to the semiconductor device. Further, it is required to provide such a semiconductor device capable of avoiding circuit destruction and of securing a sufficiently high switching speed even when a large voltage dividing resistance is added to the semiconductor device.

### First Embodiment

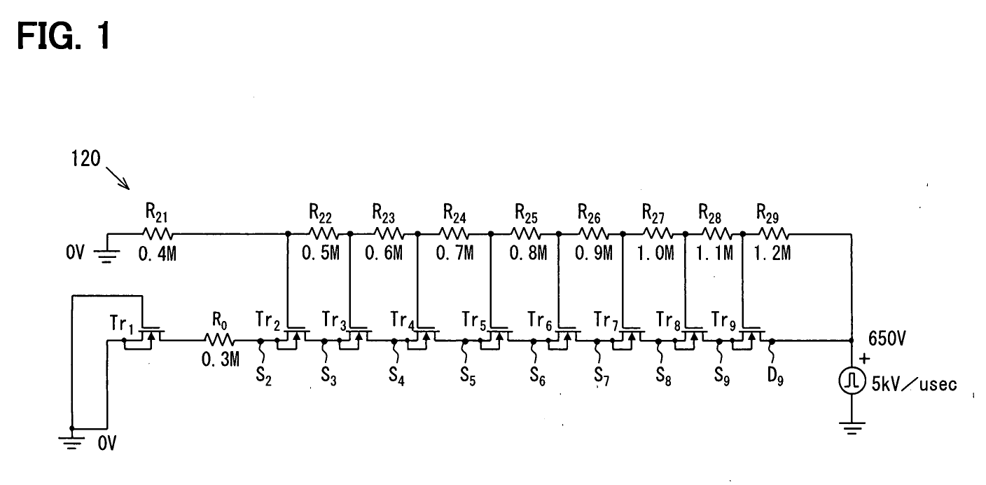

In view of the above points, a semiconductor device 120 of a first embodiment of the present invention is provided. FIG. 1 is an equivalent circuit diagram related to the semiconductor device 120 of a first embodiment.

The equivalent circuit diagram of the semiconductor device 120 shown in FIG. 1 owns a basically same arrangement with respect to the equivalent circuit diagram of the semiconductor device 100 shown in FIG. 24.

That is, in the semiconductor device 120 shown in FIG. 1, 9 pieces of transistor elements “Tr₁” to “Tr₉”, which are insulated/isolated from each other, are sequentially connected in a series connection manner between a ground (GND) potential of 0 V and a power supply potential of 650 V under such a condition that the GND-sided transistor element is defined as a first stage and the power supply-sided transistor element is defined as a ninth stage. 9 pieces of the transistor elements Tr₁ to Tr₉ of the semiconductor device 120 shown in FIG. 1 are LDMOS (Lateral Double-diffused Metal Oxide Semiconductor) type transistor elements, but may be realized by IGBT (Insulated Gate Bipolar Transistor) elements. The above-described arrangement is such an arrangement that a drain voltage of a MOS type transistor element provided at the low stage is applied to a source of a MOS type transistor element provided at the upper stage.

Also, 9 pieces of resistance elements “R₂₁” to “R₂₉⇄ are sequentially connected in a series connection manner between the same GND potential of 0 V and the power supply potential of 650 V in such a manner that the GND-sided resistance element is defined as a first stage and the power supply-sided resistance element is defined as a ninth stage.

On the other hand, different from the semiconductor device 101 of FIG. 29, in the semiconductor device 120 of FIG. 1, assuming now that symbol “i” is an arbitrary integer which is larger than, or equal to 1 and smaller than, or equal to 8 in 9 pieces of the resistance elements R₂₁ to R₂₉, a resistance value of an “i”th-staged resistance element R₂ᵢ has been set to be smaller than a resistance value of an (i+1)th-staged resistance element R₂₍ᵢ₊₁₎. In other words, as to resistance values of adjoining resistance elements, the resistance value of the lower-staged resistance element on the GND side has been set to be smaller than that of the upper-staged resistance element on the power supply side.

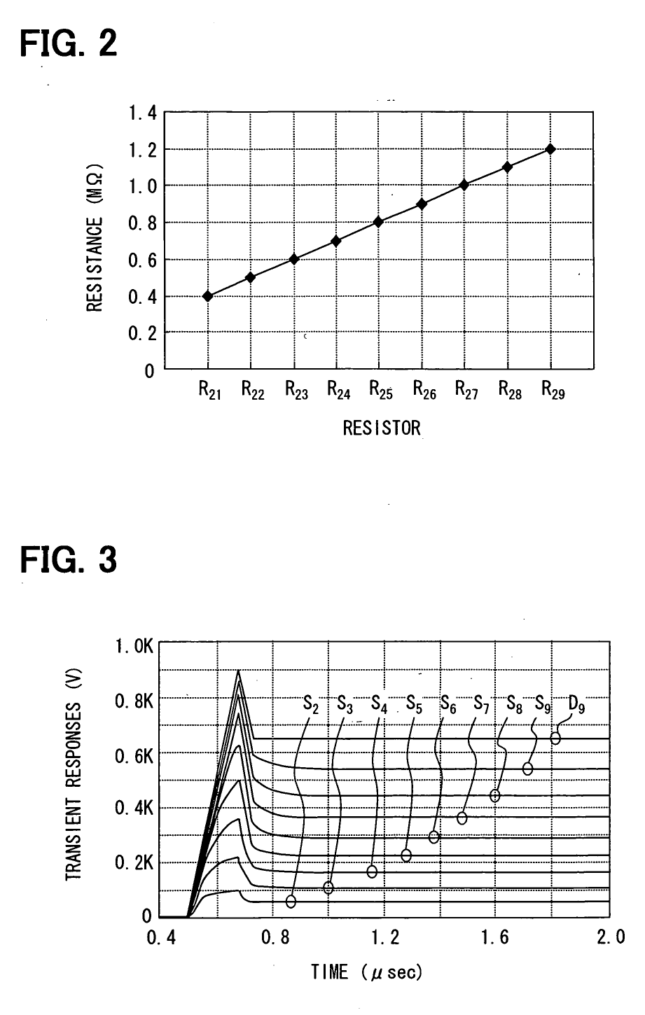

FIG. 2 is a graphic diagram for graphically showing the resistance values of 9 pieces of the resistance elements R₂₁ to R₂₉ of the semiconductor device 120. In the semiconductor device 120, a difference between the resistance value of the above-explained (i+1)th-staged resistance element R₂(i+1) and the resistance value of the “i”th-staged resistance element R₂ᵢ is equal to a constant value (namely, 0.1 MΩ) over all of “i.” In other words, the resistance values of 9 pieces of the resistance elements R₂₁ to R₂₉ which are series-connected between the GND potential of 0 V and the power supply potential of 650 V have been set in such a manner that these resistance values are linearly decreased from 1.2 MΩ to 0.4 MΩ toward the GND side. Under a stationary condition of the semiconductor device 120, a very small current flows through 9 pieces of the resistance elements R₂₁ to R₂₉, and the voltage of 650 V between the GND and the power supply is subdivided by the respective resistance elements R₂₁ to R₂₉. As previously explained in FIG. 29, a resistance element R_{O} having a resistance value of 0.3 MΩ has been inserted so as to adjust the current flowing through the transistor elements Tr₁ to Tr₉.

In the semiconductor device 120 of FIG. 1, gate terminals of the transistor elements Tr₂ to Tr₉ of the respective stages except for the first-staged transistor element Tr₁ are sequentially connected to junction points among the resistance elements R₂₁ to R₂₉ of the respective stages, which are series-connected to each other.

The gate terminal of the transistor element Tᵣ₁ of the first stage constitutes an input terminal of the semiconductor device 120. An output signal of the semiconductor device 120 is derived from the terminal of the drain D9 side of the transistor element Tr₉ of the ninth stage. It should also be noted that the output signal of the semiconductor device 120 is derived under such a condition that the reference potential is level-shifted from the GND potential of 0 V to the power supply potential of 650 V with respect to the input signal.

As previously explained in the semiconductor device 100 of FIG. 24, in the semiconductor device 120 of FIG. 1, since the input signal is applied to the gate terminal of the transistor element Tr₁ of the first stage, the transistor elements Tr₂ to Tr₉ from the second stage to the ninth stage can be simultaneously operated via 9 pieces of the resistance elements R₂₁ to R₂₉ which are similarly series-connected between the GND potential of 0 V and the power supply potential of 650 V. In other words, a drain potential of the transistor element Tᵣ₁ of the first stage is lowered when a signal voltage is applied to the gate terminal of the transistor element Tᵣ₁ of the first stage. In conjunction with this operation, since a source potential of the transistor Tr₂ of the second stage is lowered, the transistor element Tr₂ of the second stage is turned on. A similar operation is repeatedly carried out up to the transistor Tr₉ of the ninth stage, so that all of the transistor elements Tr₁ to Tr₉ are turned on within a very short time.

In operations of the semiconductor device 120 shown in FIG. 1 under normal condition, the voltage of 650 V between the GND potential and the power supply voltage is subdivided by 9 pieces of these transistor elements Tr₁ to Tr₉, and thus, the respective transistor elements Tr₁ to Tr₉ from the first stage to the ninth stage share respective voltage ranges. As a consequence, withstanding voltages required for the respective transistor elements Tr₁ to Tr₉ can be reduced, as compared with such a withstanding voltage case that the voltage of 650 V between the GND potential and the power supply potential is shared by a single transistor element. As a result, these transistor elements can be manufactured in low cost by employing a general-purpose manufacturing method, and even if transistor elements having normal withstanding voltages are employed, properly selected numbers of these transistor elements are series-connected to each other, so that such a semiconductor device capable of securing a required high withstanding voltage can be realized.

FIG. 3 represents a simulation result of the semiconductor device 120 of FIG. 1 in such a case that dV/dt surge of 5 KV/μsec is inputted. Respective graphs indicated by symbols S2 to S9 and D9 in this drawing show potentials at the respective points denoted in FIG. 1, and show source potentials of the transistor elements Tr₂ to Tr₉ and a drain potential of the transistor element Tr₉, respectively.

As apparent from a comparison between the simulation result of FIG. 3 and the simulation result of FIG. 30, in FIG. 30, when the dV/dt surge of 5 kV/μ sec was entered, the potential at the point S2 was instantaneously increased, and such a potential difference which is higher than, or equal to a half of the power supply voltage was applied to the first-staged transistor element Tr₁. In contrast thereto, in FIG. 3, even at a time instant when the dV/dt surge of 5 KV/μ sec is entered, the potentials at the respective points shown by symbols S2 to S9 and D9 are substantially uniformly distributed, and voltages caused by the surge are substantially equally applied to 9 pieces of the transistor elements Tr₁ to Tr₉.

In the semiconductor device 101 shown in FIG. 29, the resistance values of the respective resistance elements R₁₁ to R₁₉ from the first stage to the ninth stage were set to the same high resistance values, namely 4 MΩ. As a result, the further the resistance element is separated from the power supply side, the larger the electric charges of the surge current are stored. Thus, the further the transistor element is separated from the power supply side, the higher the voltage is applied thereto. As a result, this transistor element is brought into the break down status, so that the circuit destruction occurs.

To the contrary, in the semiconductor device 120 of FIG. 1, the further the resistance element is separated from the power supply side, the smaller the resistance value thereof is set, so that electric charges of the surge current can be hardly stored. As a consequence, the electric charges of the surge current can be quickly escaped (conducted) to the ground GND. Accordingly, in the transistor element separated from the power supply side, no high voltage caused by the surge is applied thereto. As a consequence, the circuit destruction by the break down of the transistor element can be suppressed.

It should be understood that as shown in FIG. 2, in the semiconductor device 120 of FIG. 1, the resistance values of 9 pieces of the resistance elements R₂₁ to R₂₉ which are series-connected between the GND potential of 0 V and the power supply potential of 650 V have been set in such a manner that these resistance values are linearly decreased toward the GND side. As a result, since the electric charges of the surge current are not stored in the specific resistance elements R₂₁ to R₂₉, the electric charges of the surge current can be uniformly escaped to the GND. Therefore, no high voltage caused by the surge is applied to the specific transistor elements Tr₁ to Tr₉, but also, the circuit destruction caused by the break down can be suppressed in the respective transistor elements Tr₁ to Tr₉.

As previously explained, the semiconductor device 120 of FIG. 1 can secure the arbitrary required withstanding voltage, and can be constructed as such a semiconductor device capable of avoiding the circuit destruction not only under the stationary condition, but also even when the surge is inputted.

It should also be understood that when the semiconductor device 120 shown in the equivalent circuit diagram of FIG. 1 is embodied, the structures of the semiconductor devices explained in FIG. 25 to FIG. 28 can be employed, and also, effects achieved by employing these structures are similar to these of the above-explained semiconductor devices. Therefore, explanations thereof are omitted.

### Second Embodiment

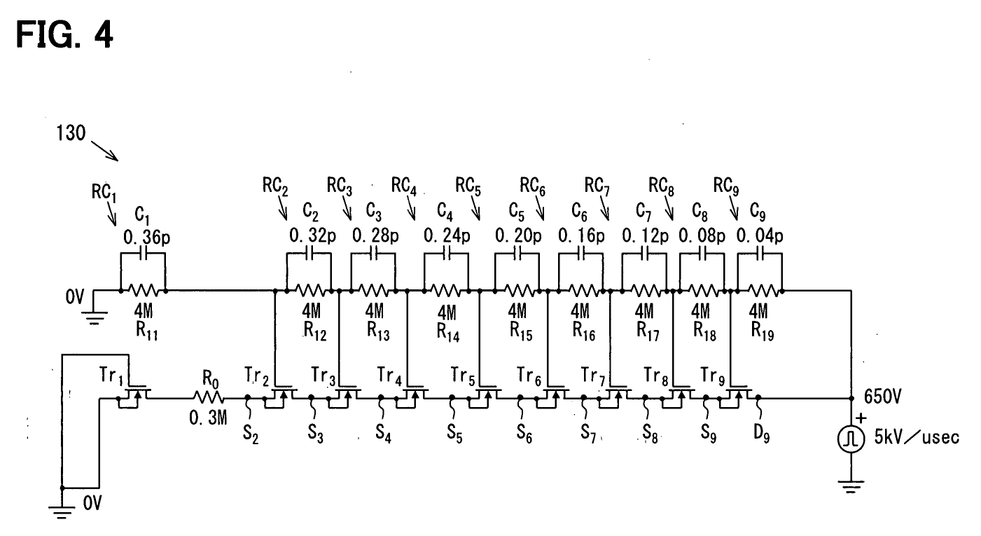

FIG. 4 is an equivalent circuit diagram related to a semiconductor device 130 of a second embodiment of the present invention.

The equivalent circuit diagram of the semiconductor device 130 shown in FIG. 4 owns a basically different arrangement with respect to the equivalent circuit diagrams of the semiconductor devices 100 and 120 shown in FIG. 24 and FIG. 1.

That is, similar to the semiconductor devices 100 and 120 shown in FIG. 24 and FIG. 1, in the semiconductor device 130 shown in FIG. 4, 9 pieces of transistor elements “Tr₁” to “Tr₉”, which are insulated/isolated from each other, are sequentially connected in a series connection manner between a ground (GND) potential of 0 V and a power supply potential of 650 V under such a condition that the GND-sided transistor element is defined as a first stage and the power supply-sided transistor element is defined as a ninth stage. It should be understood that 9 pieces of the transistor elements Tr₁ to Tr₉ in the semiconductor device 130 shown in FIG. 4 own the same withstanding voltages. As a result, as will be explained in detail, voltages (withstanding voltages) shared by the respective transistor elements Tr₁ to Tr₉ can be made equal to each other, and can be minimized.

On the other hand, different from the semiconductor devices 100 and 120 shown in FIG. 24 and FIG. 1, in the semiconductor device 130 represented in FIG. 4, while a resistance element and a second capacitance element which are parallel-connected to each other are defined as a parallel RC element, 9 pieces of parallel RC elements “RC₁” to “RC₉” are sequentially series-connected to each other between the same GND potential of 0 V and the power supply potential of 650 V in such a manner that the parallel RC element on the GND side is defined a first stage, and the parallel RC element on the power supply side is defined as a ninth stage.

In 9 pieces of the parallel RC elements RC₁ to RC₉, similar to the semiconductor device 101 of FIG. 29, resistance values of the respective resistance elements R₁₁ to R₁₉ are set to the same large resistance values, namely 4 MΩ. Under a stationary condition of the semiconductor device 130, a very small current flows through 9 pieces of the resistance elements R₁₁ to R₁₉, and the voltage of 650 V between the GND and the power supply is subdivided by the respective resistance elements R₁₁ to R₁₉.

On the other hand, in 9 pieces of the parallel RC elements RC₁ to RC₉, as to each of second capacitance elements C₁ to C₉, assuming now that symbol “j” is an arbitrary integer which is larger than, or equal to 1, and smaller than, or equal to 8, a capacitance value of a second capacitance element Cⱼ which constitutes a (j)th-staged parallel RC element RCⱼ is set to be larger than a capacitance value of a second capacitance element Cⱼ₊₁ which constitutes a (j+1)th-staged parallel RC element RCⱼ₊₁.

Also, a capacitance value of the second capacitance element C₉ which constitutes the 9th-staged parallel RC element RC₉ is set to be equal to a gate capacitance of the ninth-staged transistor element. A difference between the capacitance value of the second capacitance element Cⱼ which constitutes the (j)th-staged parallel RC element RCⱼ and the capacitance value of the second capacitance element Cⱼ₊₁ which constitutes the (j+1)th-staged parallel RC element RCⱼ₊₁ is set to be equal to a gate capacitance of the (j)th-staged transistor element Trⱼ.

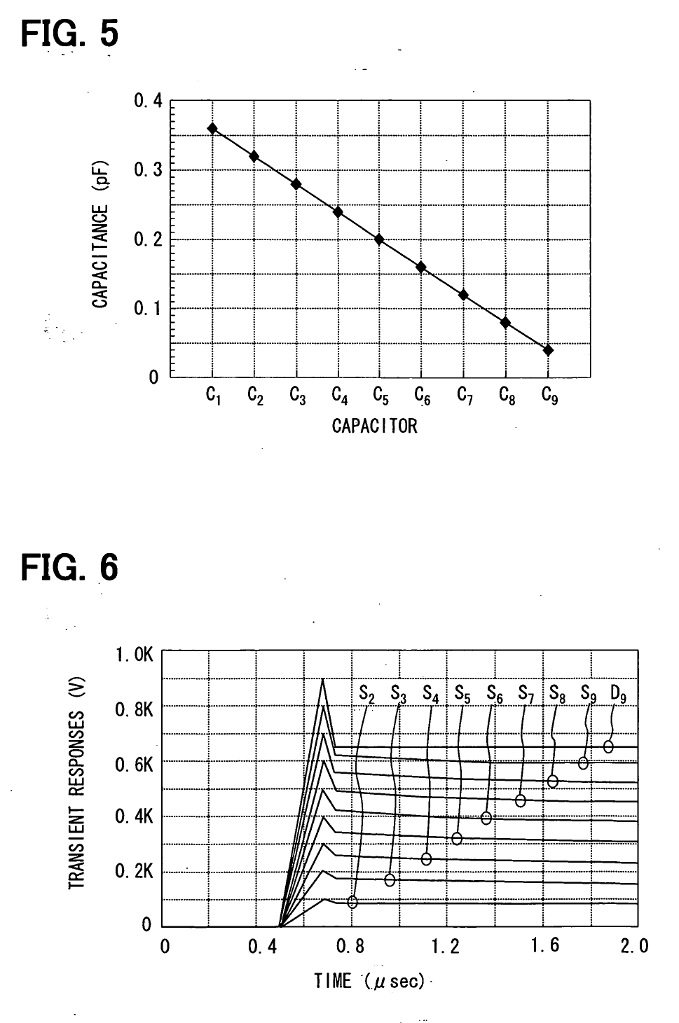

FIG. 5 is a graph for graphically representing the capacitance values of the second capacitance elements C₁ to C₉ in 9 pieces of the parallel RC elements RC₁ to RC₉ of the semiconductor device 130. In the semiconductor device 130, the difference between the capacitance value of the second capacitance element Cⱼ which constitutes the (j)th-staged parallel RC element RCⱼ and the capacitance value of the second capacitance element Cⱼ₊₁ which constitutes the (j+1)th-staged parallel RC element RCⱼ₊₁ is set to be equal to a constant value, namely 0.04 pF over all of (j). In other words, the capacitance values of 9 pieces of the second capacitance elements C₁ to C₉ which are series-connected between the GND potential of 0 V and the power supply potential of 650 V are set in such a manner that the capacitance values are linearly increased from 0.04 pF up to 0.36 pF toward the GND side. It should also be noted that in the semiconductor device 130 of FIG. 4, 9 pieces of these transistor elements Tr₁ to Tr₉ are constituted by such transistor elements having the same structures and the same withstanding voltages, and 0.04 pF equal to the difference between the capacitance value of the second capacitance element Cⱼ and the capacitance value of the second capacitance element Cⱼ₊₁ is made equal to each of the gate capacitances of the respective transistor elements Tr₁ to Tr₉.

In the semiconductor device 130 of FIG. 4, gate terminals of the transistor elements Tr₂ to Tr₉ of the respective stages except for the first-staged transistor element Tr₁ are sequentially connected to junction points among the parallel RC elements RC₁ to RC₉ of the respective stages which are series-connected to each other.

The gate terminal of the transistor element Tr₁ of the first stage constitutes an input terminal of the semiconductor device 130. An output signal of the semiconductor device 130 is derived from the terminal of the drain D9 side of the transistor element Tr₉ of the ninth stage. It should also be noted that the output signal of the semiconductor device 130 is derived under such a condition that the reference potential is level-shifted from the GND potential of 0 V to the power supply potential of 650 V with respect to the input signal.

In the semiconductor device 130 of FIG. 4, since the input signal is applied to the gate terminal of the transistor elements Tr₁ of the first stage, the transistor elements Tr₂ to Tr9 from the second stage to the ninth stage can be simultaneously operated via 9 pieces of the parallel RC elements RC₁ to RC₉ which are similarly series-connected between the GND potential of 0 V and the power supply potential of 650 V.

In operations of the semiconductor device 130 shown in FIG. 4 under normal condition, the voltage of 650 V between the GND potential and the power supply voltage is subdivided by 9 pieces of these transistor elements Tr₁ to Tr₉, and thus, the respective transistor elements Tr₁ to Tr₉ from the first stage to the ninth stage share respective voltage ranges. As a consequence, each of withstanding voltages required for the respective transistor elements Tr₁ to Tr₉ becomes approximately 1/9, as compared with such a withstanding voltage case that the voltage of 650 V between the GND potential and the power supply potential is shared by a single transistor element. As a result, even if transistor elements having normal withstanding voltages are employed, such a semiconductor device capable of securing a required high withstanding voltage can be realized.

FIG. 6 shows a simulation result as to the semiconductor device 130 of FIG. 4 in such a case that dV/dt serge of 5 KV/μ sec is inputted. Respective graphs indicated by symbols S2 to S9 and D9 in this drawing show potentials at the respective points denoted in FIG. 4, and indicate source potentials of the transistor elements Tr₂ to Tr₉, and a drain potential of the transistor element Tr₉, respectively.

Also, in the simulation result of the semiconductor device 130 shown in FIG. 6, similar to the simulation result of the semiconductor device 120 indicated in FIG. 3, an increase of the potential at the point S2 at a time instant when such a surge appeared in the simulation result of the semiconductor device 101 shown in FIG. 30 is suppressed. As represented in FIG. 6, in the semiconductor device 130 of FIG. 4, even at a time instant when the dV/dt surge of 5 KV/μ sec is entered, the potentials at the respective points shown by symbols S2 to S9 and D9 are substantially uniformly distributed, and voltages caused by the surge are substantially equally applied to 9 pieces of the transistor elements Tr₁ to Tr₉. Also, as apparent from the comparison between the simulation results shown in FIG. 6 and FIG. 3, in the simulation result of FIG. 3, the potentials at the respective points S2 to S9 and D9 are not uniformly distributed, which are located at the right end of the graph when the surge was entered and 1.5 μsec has elapsed (stationary condition). To the contrary, in the simulation result of FIG. 6, these potentials are uniformly distributed.

In the semiconductor device 130 of FIG. 4, the respective resistance elements R₁₁ to R₁₉ employed in 9 pieces of the parallel RC elements RC₁ to RC₉ become same high resistance values of 4 MΩ. As a consequence, as previously explained, in the operations of the semiconductor device 130 under normal condition, the same voltages are applied to 9 pieces of these transistor elements Tr₁ to Tr₉, and the voltage of 650 V between the GND potential and the power supply voltage is equally subdivided by 1/9. As a consequence, the withstanding voltages of the respective transistor elements Tr₁ to Tr₉ required under the normal condition can be minimized.

Also, in the semiconductor device 130 of FIG. 4, the further the second capacitance element in the parallel RC element is separated from the power supply side, the larger the capacitance value is set, so that electric charges can be hardly stored. As a result, in the operation in such a case that the surge is applied to the semiconductor device 130, the electric charges of the surge current can be quickly escaped to GND via the second capacitance elements C₁ to C₉ of the parallel RC elements RC₁ to RC₉ which are sequentially series-connected between GND and the power supply. Therefore, in the transistor element separated from the power supply side, no high voltage caused by the surge is applied thereto.

In the semiconductor device 130 of FIG. 4, the capacitance value of the second capacitance element C₉ which constitutes the ninth-staged parallel RC element RC₉ is set to be equal to the gate capacitance of 0.04 pF as to the ninth transistor element Tr₉. Also, the difference between the capacitance value of the second capacitance element Cⱼ which constitutes the (j)th-staged parallel RC element RCⱼ and the capacitance value of the second capacitance element Cⱼ₊₁ which constitutes the (j+1)th-staged parallel RC element RCⱼ₊₁ is set to be equal to the gate capacitance of 0.04 pF as to the (j)th-staged transistor element Trⱼ. Accordingly, the electric charges of the surge current are not stored in the gates of the specific transistor elements Tr₁ to Tr₉ and the specific second capacitance elements C₁ to C₉, so that the electric charges of the surge current can be quickly and uniformly escaped to the GND. As a consequence, no high voltage caused by the surge is applied to the specific transistor elements Tr₁ to Tr₉, and even when 9 pieces of the transistor elements Tr₁ to Tr₉ own the general-purpose withstanding voltages, the circuit destruction caused by the break down can be suppressed in the respective transistor elements Tr₁ to Tr₉.

It should also be understood that in the semiconductor device 130 of FIG. 4, the respective transistor elements Tr₁ to Tr₉ own the same withstanding voltages. However, the present invention is not limited only to this condition, but may be modified by that transistor elements having arbitrary withstanding voltages are combined with each other. In this alternative case, capacitance values of second capacitance elements, and resistance values of resistance elements, which constitute the respective parallel RC elements, are properly set, it is possible to avoid that the high voltage caused by the surge is applied to the respective transistor elements. Thus, in the respective transistor elements, it is possible to suppress the circuit destruction caused by the break down.

As previously explained, the semiconductor device 130 of FIG. 4 can also secure the arbitrary required withstanding voltage, and can be constructed as such a semiconductor device capable of avoiding the circuit destruction not only under the stationary condition, but also even when the surge is inputted.

It should also be understood that when the semiconductor device 130 shown in the equivalent circuit diagram of FIG. 4 is embodied, the structures of the semiconductor devices explained in FIG. 25 to FIG. 28 can be employed, and also, effects achieved by employing these structures are similar to these of the above-explained semiconductor devices. Therefore, explanations thereof are omitted. However, both the resistance elements and the second capacitance elements may be alternatively formed based upon the below-mentioned structures.

The resistance elements are not limited only to, for example, resistance elements using an impurity region of a semiconductor substrate as shown in FIG. 28, but also may be formed by employing a polysilicon film containing an impurity or Cr—Si metallic film.

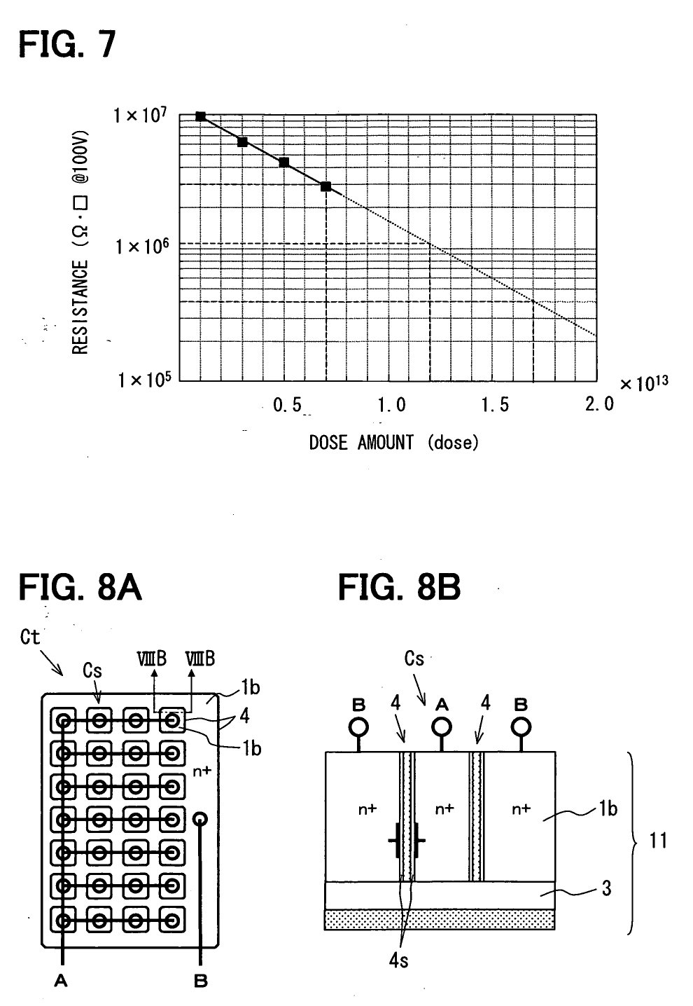

FIG. 7 is a diagram for indicating a dose amount depending characteristic as to a sheet resistance value of a polysilicon film when ions of boron (B) are implanted into a polysilicon film having a thickness of 370 nm.

As indicated in FIG. 7, when ions of boron are implanted into the polysilicon film by a low concentration dose amount of approximately 1×10¹³ dose, a sheet resistance having a value of approximately 1 MΩ is obtained. This polysilicon film is patterned so as to form a resistance element, while a resistance value of the resistance element may be set based upon a ratio of a width (W) to a length (L) of the patterned polysilicon film. As previously explained, as to the resistance element using the polysilicon film which contains the impurity, the resistance element having the high resistance value can be manufactured in high precision, as compared with the resistance element using the impurity region of the semiconductor substrate.

The second capacitance elements C₁ to C₉ employed in the semiconductor device 130 of FIG. 4 require the withstanding voltages substantially equal to those of the transistor elements Tr₁ to Tr₉, and may be formed by such a structure that an insulating/isolating trench 4 shown in FIG. 23 and FIG. 27 is a dielectric layer. For instance, in the case that a thickness of a side wall oxide film 4_{S} of the insulating/isolating trench 4 is 670 nm, a withstanding voltage of approximately 400 V can be secured.

FIG. 8A and FIG. 8B are diagrams for indicating a second capacitance element “Ct” having the above-described structure. FIG. 8A is an upper view for schematically showing the second capacitance element Ct, and FIG. 8B is a sectional view of the second capacitance element Ct, taken along a line VIIIB-VIIIB of FIG. 8A. It should also be understood that a semiconductor substrate 11 where the second capacitance element Ct of FIG. 8A and FIG. 8B has been formed is identical to the semiconductor substrate 11 having the SOI structure shown in FIG. 27 and FIG. 28, and the same reference numerals are applied.

The second capacitance element Ct shown in FIG. 8A and FIG. 8B is formed by utilizing a high concentration impurity region 1b which is formed in the SOI layer, and has the same “n” conductivity type as that of the SOI layer, and further, owns the higher impurity concentration. As shown in FIG. 8A, in the second capacitance element Ct, the high concentration impurity region 1b is segmented by the insulating/isolating trench 4, a large number of cells Cs are formed, and the respective cells Cs are connected parallel to each other.

As apparent from FIG. 8A and FIG. 8B, in the second capacitance element Ct, the insulating/isolating trench 4 which is reached to the embedded oxide film 3 is made of a dielectric layer. Also, in the second capacitance element Ct, the high concentration impurity regions 1b are used as electrodes which have been formed by sandwiching the insulating/isolating trench 4 on both sides. The structure of this capacitance element is indicated by circuit symbol of capacitance elements by a wide line in FIG. 8B. Reference numeral 4_{S} shown in FIG. 8B denotes a side wall oxide film of the insulating/isolating trench 4.

In the second capacitance element Ct having the structure shown in FIG. 8A and FIG. 8B, a capacitance value of each of the cells Cs which constitute this second capacitance element Ct depends upon a thickness of the side wall oxide film 4_{S} and a circumferential length of each cell Cs.

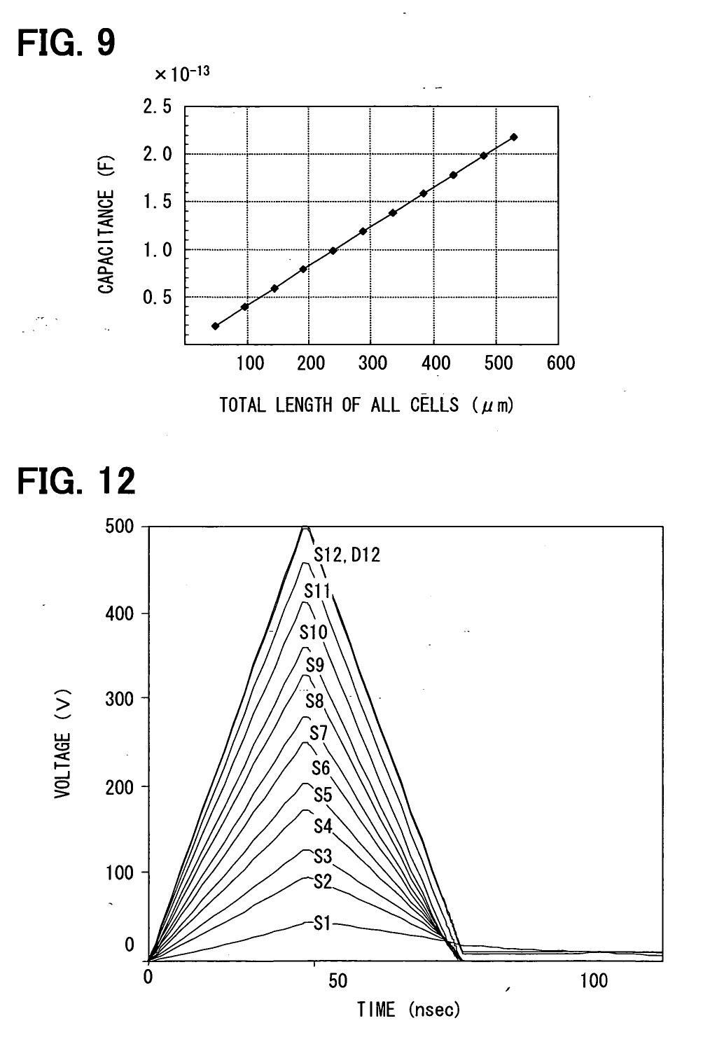

FIG. 9 graphically shows an investigation result as to a relationship between the circumferential lengths of all cells Cs and the capacitance values in FIG. 8A in the case that the thickness of the sidewall oxide film 4_{S} is 670 nm. In the semiconductor device 130 of FIG. 4, the second capacitance elements having the capacitance values from 0.04 pF to 0.36 pF are employed. As a result of FIG. 9, for example, in order to secure such a capacitance value larger than, or equal to 0.2 pF, the circumferential lengths of all cells Cs must be set to be longer than, or equal to 500 μm.

In accordance with the structures shown in FIG. 8A and FIG. 8B, the second capacitance elements C₁ to C₉ shown in FIG. 4 can be simultaneously formed by employing the manufacturing steps for the transistor elements Tr₁ to Trₙ shown in FIG. 4 and FIG. 27. As a result, the manufacturing cost of the semiconductor device 100 shown in FIG. 4 can be reduced.

### Other Embodiments

The semiconductor devices 120 and 130 shown in the first embodiment and the second embodiment correspond to such semiconductor devices made by combining 9 pieces of the transistor elements with either 9 pieces of the resistance elements or the parallel RC elements. However, the semiconductor device of the present invention is not limited only to the above-explained semiconductor devices, but may be realized by a semiconductor device made by combining arbitrary “n” pieces of transistor elements with the same “n” pieces of resistance elements, or of parallel RC elements. Symbol “n” is larger than, or equal to 2.

Also, the semiconductor devices 120 and 130 indicated in the first embodiment and the second embodiment are suitable for the semiconductor device employed in the level shift circuit in the high voltage IC 110 for driving the inverter as shown in FIG. 25. This high voltage IC 110 is arranged by the GND reference gate driving circuit, the floating reference gate driving circuit, the control circuit, and the level shift circuit. As a consequence, the high voltage IC 110 shown in FIG. 25 which employs the semiconductor devices 120 and 130 can secure the withstanding voltage of 1200 V, and may constitute a suitable high voltage IC for driving an inverter of an on-vehicle motor, and an inverter of an on-vehicle air conditioner. However, the semiconductor device of the present invention is not limited only to these high voltage IC_{S}, but may be applied to an arbitrary semiconductor device which requires a high withstanding voltage, and a level shift between the ground (GND) potential and a predetermined potential. Alternatively, the semiconductor device of the present invention may be applied to motor control fields for commercial and industrial purposes.

A semiconductor device according to the present invention may be manufactured by employing other structures than the semiconductor devices 120 and 130 shown in the first embodiment and the second embodiment.

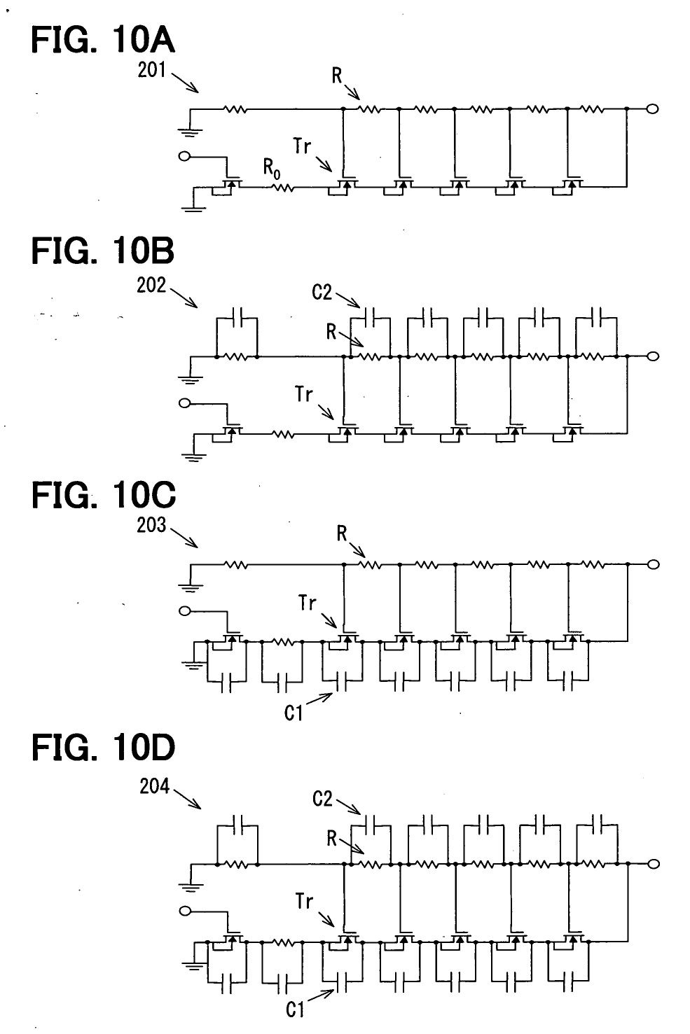

FIG. 10A to FIG. 10D are diagrams for schematically indicating basic structures of semiconductor devices according to a modification of the present invention, namely, diagrams for showing semiconductor devices 201 to 204 having different structures.

The semiconductor device 201 shown in FIG. 10A has a similar structure to that of the semiconductor device 120 shown in FIG. 1 of the first embodiment. That is, a voltage between the GND potential and a predetermined potential is subdivided by “n(n≧2)” pieces of transistors Tr and “n” pieces of resistance elements R. In the semiconductor device 120 of the first embodiment, since the resistance values of “n” pieces of the resistance elements R are properly set, the potentials at the respective points indicated by S2 to S9 and D9 in the lines of “n” pieces of the transistor elements Tr in the case that the dV/dt surge is entered may become substantially equal to each other.

The semiconductor device 202 shown in FIG. 10B has a similar structure to that of the semiconductor device 130 shown in FIG. 4 of the second embodiment. That is, a voltage between the GND potential and a predetermined potential is subdivided by “n(n≧2)” pieces of transistors Tr and “n” pieces of resistance elements R, and “n” pieces of parallel RC elements. In “n” pieces of the parallel RC elements, resistance elements R and second capacitance elements C2 which are connected parallel to each other are employed as parallel RC elements. In the semiconductor device 130 of the second embodiment, since the resistance values of the resistor elements R and the capacitance values of the second capacitance elements C2 provided in “n” pieces of the parallel RC elements are properly set, the potentials at the respective points indicated by S2 to S9 and D9 in the lines of “n” pieces of the transistor elements Tr in the case that the dV/dt surge is entered may become substantially equal to each other.

In view of another aspect, the structure of the semiconductor device 202 of FIG. 10B is made as follows: That is, the line of the series-connected second capacitance elements C2 is additionally provided between the GND potential and the predetermined potential with respect to the semiconductor device 201 of FIG. 10A. The line of the series-connected second capacitance elements C2 may be conceived as a function of such a line capable of escaping a surge current in the case that the resistance values of the resistance elements R are large when dV/dt surge is entered.

Also, a similar function may be expected in the semiconductor devices 203 and 204 shown in FIG. 10C and FIG. 10D.

A structure of the semiconductor device 203 of FIG. 10C is arranged by that a first capacitance element C1 is parallel-connected to each of “n” pieces of the transistor elements Tr with respect to the semiconductor device 201 of FIG. 10A.

In view of another aspect, the structure of the semiconductor device 203 of FIG. 10C is made as follows: That is, the line of the series-connected first capacitance elements C1 is additionally provided between the GND potential and the predetermined potential with respect to the semiconductor device 201 of FIG. 10A.

Similar to the semiconductor device 201 of FIG. 10A, also, in the semiconductor device 203 of FIG. 10C, since an input signal is supplied to a gate terminal of a transistor element Tr of a first stage, transistor elements from a second stage to an “n”-th stage can be simultaneously operated via “n” pieces of resistance elements “R” which are series-connected between the GND potential and a predetermined potential. Also, in operations of the normal condition, a voltage between the GND potential and the predetermined potential is subdivided by “n” pieces of transistor elements Tr. As a result, the withstanding voltage required for each of the transistor elements Tr can be reduced by approximately 1/n, and such a semiconductor device capable of securing a high withstanding voltage required as the entire device can be manufactured.

On the other hand, different from the semiconductor device 201 of FIG. 10A, the structure of the semiconductor device 203 of FIG. 10C is arranged by that the first capacitance element C1 is parallel-connected to each of “n” pieces of the transistor elements Tr. Since “n” pieces of the transistor elements Tr are series-connected between the GND potential and the predetermined potential, these parallel-connected first capacitance elements C1 are similarly series-connected between the GND potential and the predetermined potential. As a result, a transfer path for AC components is formed between the GND potential and the predetermined potential.

Also, in switching operation of the semiconductor device 203 of FIG. 10C, the transfer path of the AC component may function as a bypass path for transferring a potential of an input signal pulse. The transfer path is constituted by the first capacitance elements C1 which are series-connected between the GND potential and the predetermined potential. In other words, when the input signal pulse rises (falls), the gate capacitances of the transistor elements Tr of the respective stages can be charged (discharged) via the bypass path. As a result, when the input signal pulse rises (falls), a signal change is quickly transferred via the bypass path to the transistor elements Tr of the respective stages. To the contrary, in the semiconductor device 201 of FIG. 10A in which the first capacitance elements C1 are not parallel-connected to the respective transistor elements Tr, when the input signal pulse is inputted, the current flows through the load resistor R_{O} to the transistor elements Tr of the respective stages, potential drops of the transistor elements Tr of the respective stages are transferred, and then, are derived as an output signal. As a result, in the semiconductor device 201 of FIG. 10A, delays are produced due to the load resistor R_{O} and the ON resistances of the transistor elements Tr. In the semiconductor device 203 of FIG. 10C in which the first capacitance elements C1 are parallel-connected to the respective transistor elements Tr, the charging/discharging path of the gate capacitance is newly secured, so that the switching speed of the semiconductor device 203 can be improved, as compared with that of the semiconductor device 201 of FIG. 10A.

Also, when surge is applied to the semiconductor device 203 of FIG. 10C, electric charges of the surge current can be quickly escaped to GND via the transfer path of the AC components, which is arranged by the first capacitance elements C1 series-connected between the GND potential and the predetermined potential. As a result, it is possible to avoid that the high voltage caused by the surge is applied to the respective transistor elements Tr, and also possible to suppress the circuit destruction caused by the break down of the transistor elements Tr.

Different from the semiconductor device 201 of FIG. 10A, in the semiconductor device 203 of FIG. 10C, even when a stray capacitance is present in the semiconductor device 203, the suppression effect of the circuit destruction in the case that the surge is applied can be achieved. In other words, since the capacitance value of the first capacitance element C1 is properly set to be larger than the stray capacitance value, the electric charges of the surge current can be quickly escaped to GND via the transfer path of the AC components constructed of the first capacitance elements C1, and also, the voltage drop caused by the stray capacitance can be canceled, so that the voltages applied to the respective transistor elements Tr can be equalized. As a result, it is possible to suppress the circuit destruction caused by the break down of the transistor elements Tr.

As previously explained, the semiconductor device 203 of FIG. 10C can secure an arbitrary required withstanding voltage, and can be manufactured as such a semiconductor device capable of being operated even when the stray capacitance is present, while no circuit is destroyed even not only under the stationary condition, but also even when the surge is entered. Furthermore, even when a high voltage dividing resistor is added, the semiconductor device 203 can secure the sufficiently high switching speed.

In the semiconductor device 203 of FIG. 10C, the capacitance value of the first capacitance element C1 must be made larger than such a stray capacitance value which may be generally produced in a semiconductor device. On the other hand, when the capacitance value of the first capacitance element C1 becomes excessively large, a current for charging the first capacitance element C1 is required. As a result, a switching speed becomes slow. Also, since the first capacitance element C1 is parallel-connected to the transistor element Tr, this first capacitance element C1 must have a withstanding voltage nearly equal to that of the transistor element Tr.

As a consequence, the capacitance value of the first capacitance element C1 is preferably selected to be larger than, or equal to 1 pF, and smaller than, or equal to 15 pF.

It should be noted that the effect explained in the semiconductor device 203 of FIG. 10C may be similarly expected also in the semiconductor device 202 of FIG. 10B.

That is to say, in the semiconductor device 202 of FIG. 10B, since the second capacitance elements C2 are series-connected between the GND potential and the predetermined potential. As a result, a transfer path for AC components is formed between the GND potential and the predetermined potential. As a consequence, in switching operation of the semiconductor device 202 of FIG. 10B, the transfer path of the AC components may function as a bypass path for transferring a potential of an input signal pulse. The transfer path is constituted by the second capacitance elements C2 which are series-connected between the GND potential and the predetermined potential. In other words, when the input signal pulse rises (falls), the gate capacitances of the transistor elements Tr of the respective stages can be charged (discharged) via the bypass path. As a result, when the input signal pulse rises (falls), a signal change is quickly transferred via the bypass path to the transistor elements Tr of the respective stages. As a consequence, similar to the semiconductor device 203 of FIG. 10C, also, in the semiconductor device 202 of FIG. 10B, the charging/discharging paths of the gate capacitances from the gate side are newly secured, so that the switching speed can be improved, as compared with that of the semiconductor device 201 of FIG. 10A.

Also, similar to the semiconductor device 203 of FIG. 10C, in the semiconductor device 202 of FIG. 10B, even when a stray capacitance is present in the semiconductor device 202, the suppression effect of the circuit destruction in the case that the surge is applied can be achieved. In other words, since the capacitance value of the second capacitance element C2 is properly set to be larger than the stray capacitance value, the electric charges of the surge current can be quickly escaped to GND via the transfer path of the AC components constructed of the second capacitance elements C2, and also, the potential drop caused by the stray capacitance can be canceled, so that the voltages applied to the respective transistor element Tr can be equalized. As a result, it is possible to suppress the circuit destruction caused by the break down of the transistor elements Tr.

It should also be understood that similar to the first capacitance element C1 in the semiconductor device 203 of FIG. 10C, the capacitance value of the second capacitance element C2 in the semiconductor device 202 of FIG. 10B must be made larger than the stray capacitance value. Also, if the capacitance value of the second capacitance value C2 becomes excessively large, the switching speed becomes eventually slow.

As a consequence, the capacitance value of the first capacitance element C1 is preferably selected to be larger than, or equal to 1 pF, and smaller than, or equal to 15 pF.

It should be noted that the effect explained above may be similarly expected also in the semiconductor device 204 of FIG. 10D.

In the semiconductor device 204 of FIG. 10D, the second capacitance elements C2 are series-connected between the GND potential and the predetermined potential, and also, the first capacitance elements C1 are series-connected between the GND potential and the predetermined potential, so that two transfer paths for AC components are formed between the GND potential and the predetermined potential. As a result, in switching operations of the semiconductor device 204 of FIG. 10D, the two transfer paths for the AC components may function as bypass paths for transferring a potential of an input signal pulse. These two transfer paths are arranged by the second capacitance elements C2 series-connected between the GND potential and the predetermined potential, and also, the first capacitance elements C1 series-connected between the GND potential and the predetermined potential. As a consequence, a switching speed of the semiconductor device 204 of FIG. 10D can be further improved, as compared with the switching speeds of the semiconductor device 202 of FIG. 10B and the semiconductor device 203 of FIG. 10C.

Also, when surge is applied to the semiconductor device 204 of FIG. 10D, the electric charges of the surge current can be quickly escaped to GND via the two transfer paths for the AC components, which are arranged by the second capacitance elements C2 series-connected between the GND potential and the predetermined potential, and also, the first capacitance elements C1 series-connected between the GND potential and the predetermined potential. As a consequence, in the semiconductor device 204 of FIG. 10D, the suppression effect as to the circuit destruction caused by the break down of the transistor elements can be furthermore improved, as compared with those of the semiconductor device 202 of FIG. 10B and the semiconductor device 203 of FIG. 10C.

Next, as to effects related to the semiconductor devices 202 to 204 shown in FIG. 10B to FIG. 10D, results of investigation tests are indicated.

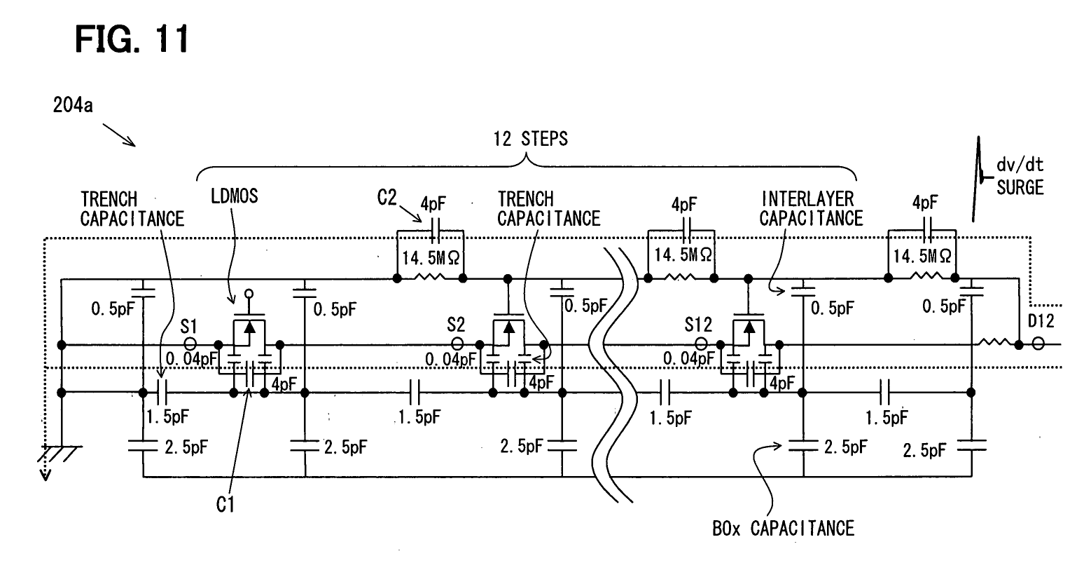

FIG. 11 and FIG. 12 show a simulation result of a semiconductor device 204a having the same structure as that of the semiconductor device 204 of FIG. 10D.

FIG. 11 is an equivalent circuit diagram of the semiconductor device 204a which is employed in the simulation. FIG. 12 indicates the simulation result of the semiconductor device 204a in the case that dV/dt surge is entered. FIG. 12 is a graph for graphically representing temporal changes in potentials in the respective points S1 to S12 on the source sides of LDMOSs of the respective stages, and a potential at the point D12 of the output resistor Rₒᵤₜ on the power supply side, which is equivalent to the potential of the dV/dt surge shown in FIG. 11.

The semiconductor device 204a shown in FIG. 11 is arranged by that a line of a first capacitance element C1 having 4 pF, and a line of a second capacitance element C2 having 4 pF are added with respect to the semiconductor device 101a indicated in FIG. 32.

As shown in FIG. 11, in the semiconductor device 110a shown in FIG. 32, when the dV/dt surge is entered, the large potential difference is produced between the point S12 and the point D12. To the contrary, as shown in FIG. 12, in the semiconductor device 204a of FIG. 11, when the dV/dt surge is entered, the potentials at the respective points S1 to S12 of the LDMOSs on the source side are equally distributed. As a consequence, the voltages applied to the respective LDMOSs when the surge is entered become equal to each other, so that the circuit destruction in the specific LDMOS can be prevented. It should also be noted that although the potentials at the points S12 and D12 become equal to each other in FIG. 12, this is caused by the circuit arrangement shown in FIG. 11, and thus, this does not constitute an essential matter.

The reason why as shown in FIG. 12, in the semiconductor device 204a of FIG. 11, when the dV/dt surge is entered, the potentials at the respective points S1 to S12 of the LDMOSs on the source side are equally distributed, is given as follows: That is, the current caused by the dV/dt surge is escaped to GND via the line of the first capacitance element C1 and the line of the second capacitance element C2 as shown in a wide dot line having arrows in FIG. 12. In the semiconductor device having the line of the first capacitance element C1 and/or the line of the second capacitance element C2, the voltage of the entered dV/dt surge is instantaneously transferred via the line of the first capacitance elements C1 and/or the line of the second capacitance element C2 to the LDMOSs of the respective stages. As a result, the voltages caused by the dV/dt surge applied to the LDMOSs of the respective stages are equalized.

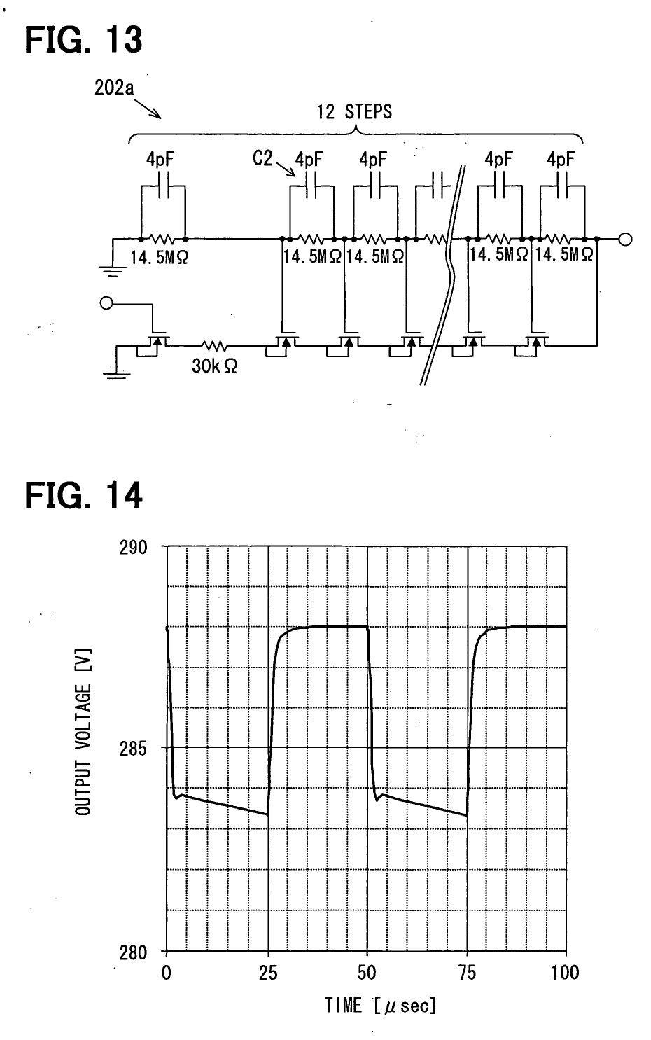

FIG. 13 and FIG. 14 show a simulation result of a semiconductor device 202a having the same structure as that of the semiconductor device 202 of FIG. 10B.

FIG. 13 is an equivalent circuit diagram of the semiconductor device 202a which is employed in the simulation. FIG. 14 indicates a simulation result which shows a response characteristic of the semiconductor device 202a with respect to a pulse signal input, namely, a diagram for representing a falling characteristic of an output potential from the power supply potential with respect to the pulse signal input.

The semiconductor device 202a shown in FIG. 13 is arranged by that a line of a second capacitance element C2 having 4 pF is added with respect to the semiconductor device 101b indicated in FIG. 33.

In the semiconductor device 101b shown in FIG. 33, as shown in FIG. 34, as seen from a response between 50 μ sec and 75 μ sec, a falling portion of an output potential when an input signal is entered becomes dull. In contrast to the above case, in the semiconductor device 202a of FIG. 13, as shown in FIG. 14, a falling characteristic of an output potential has been improved. This reason is given as follows: That is, even when high resistors are added to the gates of the LDMOSs of the respective stages and the drain of the input stage, since the line of the second capacitance element C2 is added, the gate capacitances of the LDMOSs of the respective stages are charged (discharged) via this line.

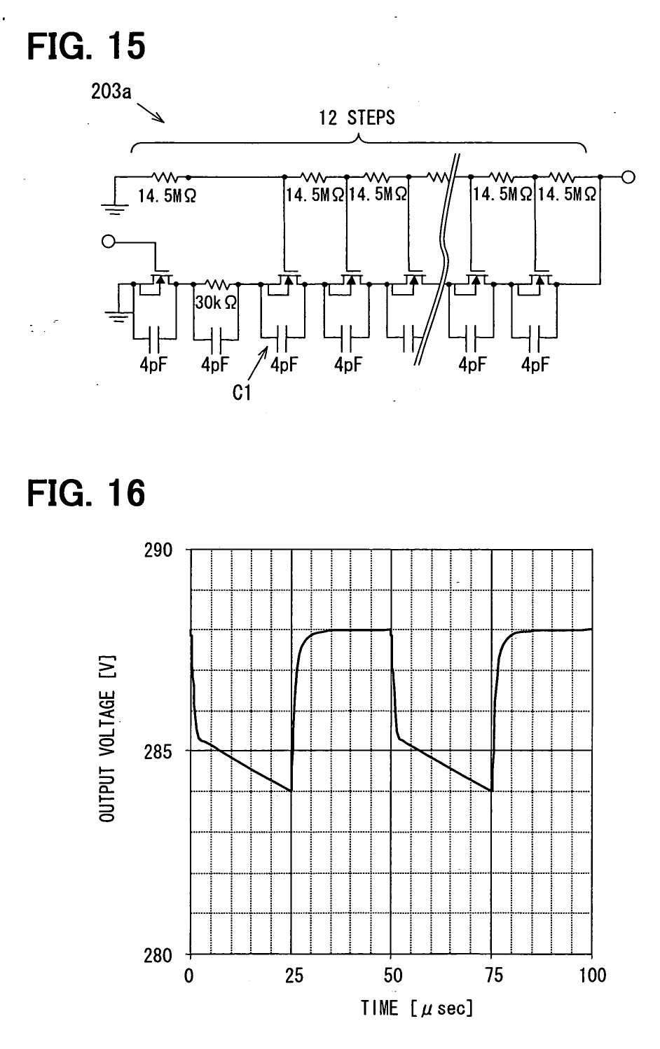

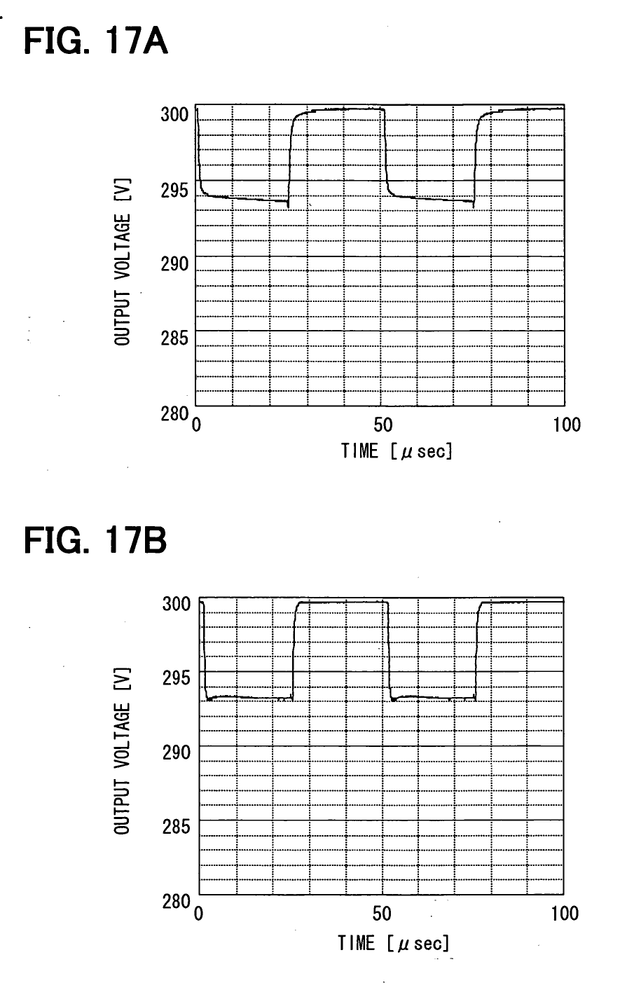

Similarly, FIG. 15 and FIG. 16 show a simulation result of a semiconductor device 203a having the same structure as that of the semiconductor device 203 of FIG. 10C.

FIG. 15 is an equivalent circuit diagram of the semiconductor device 203a which is employed in the simulation. FIG. 16 indicates a simulation result which shows a response characteristic of the semiconductor device 203a with respect to a pulse signal input, namely, a diagram for representing a falling characteristic of an output potential from the power supply potential with respect to the pulse signal input.

The semiconductor device 203a shown in FIG. 15 is arranged by that a line of a first capacitance element C1 having 4 pF is added with respect to the semiconductor device 101b indicated in FIG. 33.

As shown in FIG. 16, also, in the semiconductor device 203a of FIG. 15, a falling characteristic of an output potential has been improved, as compared with the falling characteristic of the semiconductor device 101b shown in FIG. 34. This reason is given as follows: That is, since the line of the first capacitance element C1 is added, the gate capacitances of the LDMOSs of the respective stages are charged (discharged) via this line.

FIG. 17A and FIG. 17B indicate actually measured evaluation results of response characteristics with respect to a pulse signal input as to the semiconductor devices 202b and 203b which own the same structures as these of the semiconductor device 202 of FIG. 10B and the semiconductor device 203 of FIG. 10C. The structures of the semiconductor devices 202b and 203b which are employed in the actually measured evaluation are represented as follows. In the semiconductor device 202b, the resistance element R is 10 MΩ, the second capacitance element C2 is 3.2 pF, the number of the LDMOSs is twelve steps, and the resistance element R₀ is 30 kΩ. In the semiconductor device 203b, the resistance element R is 10 MΩ, the first capacitance element C1 is 1.6 pF, the number of the LDMOSs is twelve steps, and the resistance element R₀ is 30 kΩ.

Similar to the simulation results of the semiconductor devices 202a and 203a shown in FIG. 14 and FIG. 16, also, in the actually measured evaluation of the response characteristic with respect to the pulse signal inputs for the semiconductor devices 202b and 203b, such a superior falling characteristic of the output potential shown in FIG. 17A and FIG. 17B can be obtained.

As previously explained, the semiconductor devices 201 to 204 shown in FIG. 10A to FIG. 10D can secure arbitrary required withstanding voltages, and can be manufactured as such semiconductor devices capable of being operated, while no circuit is destroyed even not only under the stationary condition, but also even when the surge is entered. Furthermore, even when a high voltage dividing resistor is added, the semiconductor devices 201 to 204 can secure the sufficiently high switching speed without the circuit destruction.

It should also be understood that capacitance elements having various sorts of structures may be employed as the first capacitance elements C1 and the second capacitance elements C2 which are used in the semiconductor devices 201 to 204 of FIG. 10A to FIG. 10D.

In FIG. 8, the structural example of the capacitance element Ct has been indicated as the second capacitance element C2. As apparent from the foregoing explanation, the capacitance element having this structure may be employed as the first capacitance element C1.

As to the first capacitance element C1 and/or the second capacitance element C2, which has the structure of the capacitance element Ct shown in FIG. 8, since the thick insulating/isolating trench 4 constitutes the dielectric layer, the higher capacitance can be hardly obtained. However, such a withstanding voltage higher than, or equal to 100 V can be easily secured. Also, since the capacitance element is formed by utilizing the trench, the occupied area can be reduced, as compared with such a case that the capacitance element is formed on the semiconductor substrate 11. Furthermore, since the capacitance elements can be simultaneously formed by employing the manufacturing steps of the transistor elements, the manufacturing cost of the semiconductor devices 201 to 204 can be reduced.

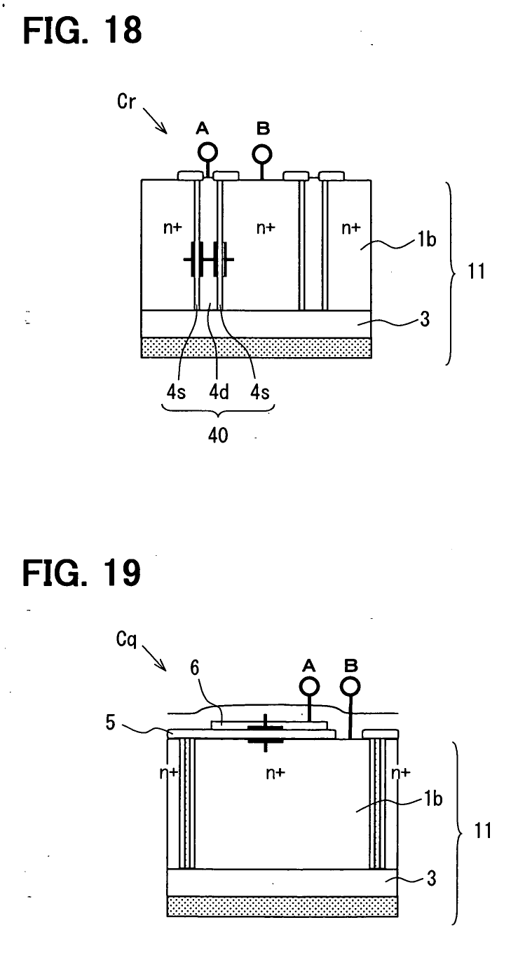

FIG. 18 is a diagram for showing a structure of another capacitance element which may be employed in the first capacitance element C1 and/or the second capacitance element C2 of FIGS. 10A to 10D, namely, FIG. 18 is a sectional view for schematically showing a capacitance element “Cᵣ.” It should also be noted that since a semiconductor substrate 11 where the capacitance element Cr of FIG. 18 is formed is the same as the semiconductor substrate 11 having the SOI structure shown in FIG. 8, the same reference numerals are applied.

The capacitance element Cr shown in FIG. 18 is made of the following structures. That is, polysilicon 4d having an electric conductivity is used as one electrode, and a high concentration impurity region 1b is used as the other electrode by sandwiching a side wall oxide film 4s. The polysilicon 4d is embedded in an insulating/isolating trench 40, while the side wall oxide film 4s of the insulating/isolating trench 40 is employed as a dielectric layer. The high concentration impurity region 1 has the same “N” conductivity as that of an SOI layer which is formed around the insulating/isolating trench 40, and owns higher impurity concentration. The structure of this impurity element Cr is indicated by a circuit symbol of a capacitance element by using a wide line in FIG. 18. A capacitance value of the capacitance element Cr is directly proportional to a product made by a circumferential length of the trench and a depth of the trench, which correspond to the film thickness of the side wall oxide film 4s and the area of the side wall oxide film 4s.

Since the capacitance element Cr shown in FIG. 18 requires a withstanding voltage higher than, or equal to 100 V, a relatively thicker side wall oxide film 4s must be employed. In the capacitance element Cᵣ, after a trench is formed by way of a dry etching process, the side wall oxide film 4s is formed. Next, the trench is embedded by high concentration polysilicon 4d so as to be used as one electrode. Also, since the capacitance elements Cr can be simultaneously formed by employing the manufacturing steps of the transistor elements, the manufacturing cost of the semiconductor devices 201 to 204 can be reduced. Also, as to the capacitance element Cr shown in FIG. 18, since the thin side wall oxide film 4s constitutes the dielectric layer, a large capacitance can be easily obtained.

FIG. 19 is a diagram for showing a structure of another capacitance element which may be employed in the first capacitance element C1 and/or the second capacitance element C2 of FIG. 10A to FIG. 10D, namely, FIG. 19 is a sectional view for schematically showing a capacitance element “C_{q}.” It should also be noted that since a semiconductor substrate 11 where the capacitance element “C_{q}” of FIG. 19 is formed is the same as the semiconductor substrate 11 having the SOI structure shown in FIG. 8, the same reference numerals are applied.

The capacitance element C_{q} shown in FIG. 19 is made of the following structures. That is, polysilicon 6 having an electric conductivity is used as one electrode, and a high concentration impurity region 1b is used as the other electrode by sandwiching an oxide film 5 corresponding to a field oxide film. The polysilicon 6 is formed on the oxide film 5, while the oxide film 5 formed on the SOI layer is used as a dielectric layer. The high concentration impurity region 1b has high concentration of an impurity, and is formed on the SOI layer, while having the same conductivity type as that of this SOI layer. The structure of this capacitance element C_{q} is indicated by using a circuit symbol for a capacitance element by a wide line in FIG. 19.

Although an area occupied by the capacitance element C_{q} shown in FIG. 19 on the semiconductor substrate 11 becomes large, these capacitance elements C_{q} can be manufactured at the same time by employing the wiring steps for the semiconductor devices 201 to 204 of FIG. 10A to FIG. 10D, so that the manufacturing cost of the semiconductor devices 201 to 204 can also be reduced by this forming step.

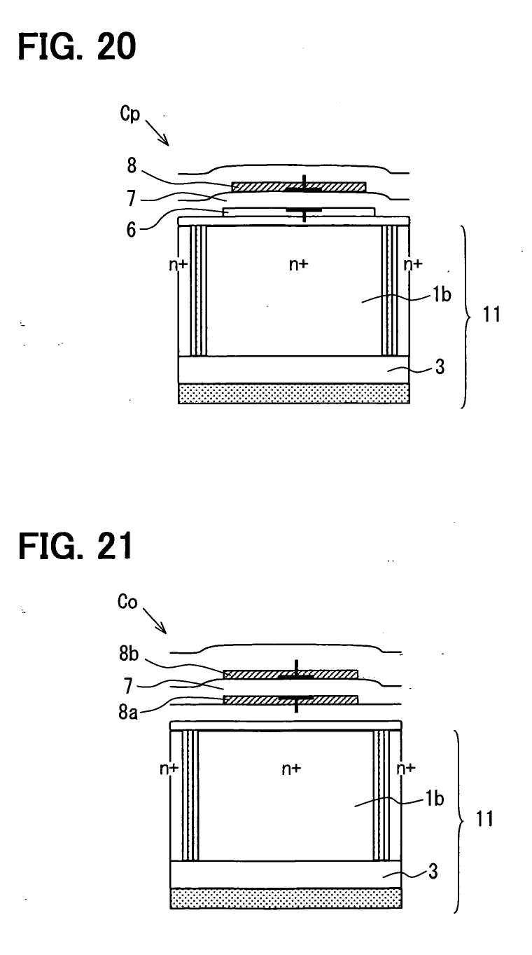

FIG. 20 is a diagram for showing a structure of another capacitance element which may be employed in the first capacitance element C1 and/or the second capacitance element C2 of FIG. 10A to FIG. 10D, namely, FIG. 20 is a sectional view for schematically showing a capacitance element “Cₚ.” The capacitance element Cₚ shown in FIG. 20 is made of the following structures. That is, polysilicon 6 formed on the oxide film and having an electric conductivity is used as one electrode, either an aluminium layer or an aluminium alloy layer 8, which are formed on an interlayer insulating film 7, is used as the other electrode by sandwiching the interlayer insulating film 7, while this interlayer insulating film 7 formed above the SOI layer is employed as a dielectric layer. The structure of this capacitance element Cₚ is indicated by using a circuit symbol for a capacitance element by a wide line in FIG. 20.

In the capacitance element Cₚ shown in FIG. 20, the polysilicon 6 utilized as a gate electrode is employed as the lower electrode; the interlayer insulating film 7 is employed as the dielectric layer; and either the aluminium layer or the aluminium alloy layer 8 is employed as the upper electrode, which are used as an aluminium wiring line. As a consequence, the capacitance elements Cₚ can be formed at the same time by employing the wiring steps of the semiconductor devices 201 to 204 shown in FIG. 10A to FIG. 10D, so that the manufacturing cost of the semiconductor devices 201 to 204 can also be reduced by this forming step. It should also be understood that if the voltage dividing resistors “R” of the semiconductor devices 201 to 204 shown in FIG. 10A to FIG. 10D are overlapped over the upper electrode 8 in some case, then the area thereof may be reduced.

FIG. 21 is a diagram for showing a structure of another capacitance element which may be employed in the first capacitance element C1 and/or the second capacitance element C2 of FIG. 10A to FIG. 10D, namely, FIG. 21 is a sectional view for schematically showing a capacitance element “C_{O}.” The capacitance element C_{O} shown in FIG. 21 is made of the following structures. That is, while an interlayer insulating film 7 between wiring lines formed above the SOI layer is employed as a dielectric layer, either aluminium layers or aluminium alloy layers 8a and 8b are employed as electrodes, which are formed on both side by sandwiching the interlayer insulating film 7.

It should also be noted that since the capacitance elements CO shown in FIG. 21 can be formed at the same time by employing the wiring steps of the semiconductor devices 201 to 204 shown in FIG. 10A to FIG. 10D, so that the manufacturing cost of the semiconductor devices 201 to 204 can also be reduced by this forming step.

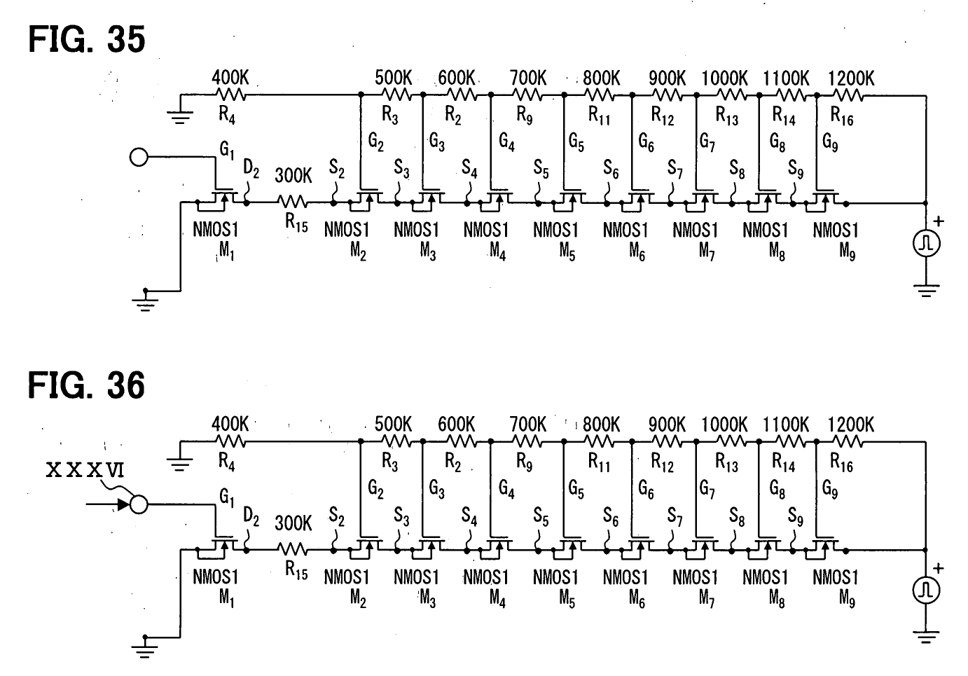

Another embodiment for improving a switching speed is shown in FIG. 35. A size (current capability) of the transistor element Tr₁ is made smaller than sizes of the transistor elements Tr₂ to Tr₉, and a change in a current value is reduced when the transistor element Tr₁ is switched. As a result, a response speed of this transistor element Tr₁ can be improved, so that the entire switching speed can be improved. Here, the size of the LDMOS, i.e., NMOS1-M1, is made smaller than the sizes of other LDMOSs (namely, current capability is reduced), so that the change in the current value during the switching operation can be reduced so as to improve the switching speed.

Further another embodiment for improving a switching speed is shown in FIG. 36. Since a voltage lower than VT of the transistor element Tr₁ is continuously applied to the gate terminal of this transistor element Tr₁, the transistor element Tr₁ is continuously set under a half ON state to flow a current. When a switching signal having a voltage higher than, or equal to VT is applied to the gate terminal of the transistor element Tr₁, a change in a current value thereof is reduced. As a result, a response speed of this transistor element Tr₁ is improved, so that the entire switching speed can be improved. Here, the voltage lower than, or equal to VT is continuously applied to a terminal XXXVI. When the transistor element is turned ON, the voltage higher than, or equal to VT is applied thereto. While a size of the LDMOS, i.e., NMOS1-M1, is set under a half ON state (voltage lower than, or equal to VT is continuously applied), the voltage higher than, or equal to VT is applied when this LDMOS is turned on, so that the switching speed can be improved.

The present invention has the following aspects.

A semiconductor device includes: a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two; an input terminal provided by a gate terminal of the first step transistor; a plurality of resistors, which are connected in series between the ground potential and the predetermined potential, wherein one of the resistors disposed on the utmost ground potential side is defined as a first step resistor, and another resistor disposed on the utmost predetermined potential side is defined as a Nth step resistor; and an output terminal provided by a predetermined potential side terminal of the Nth step transistor. A gate terminal of each transistor other than the first step transistor is sequentially connected between neighboring two resistors. One of the resistors defined as an Ith step resistor has a resistance, which is smaller than a resistance of a (I+1)th step resistor, and I is a given natural number in a range between one and (N-1).

In the above device, when the input signal is inputted into the gate terminal of the first transistor, the second to the Nth transistors can be operated simultaneously through N resistors, which are connected in series between the GND potential and the predetermined potential. When the device is operated under a normal condition, the voltage between the GND potential and the predetermined potential is divided by N transistors so that each voltage range is distributed in each transistor. Accordingly, the withstand voltage of each transistor, which is required for each transistor, is reduced, compared with a case where only one transistor covers the voltage between the GND potential and the predetermined potential. Thus, even when each transistor has a conventional withstand voltage, the device has high withstand voltage as a whole.

Further, when each resistor has the same high resistance, the charge of the surge current is accommodated in the resistor, which is disposed far from the power source of the predetermined potential, so that the surge current cannot be discharged to the GND side. Accordingly, a high voltage is applied to the transistor disposed far from the power source, so that the transistor may be broken, and the total circuit may be destroyed. However, in the above device, the resistance of the resistor becomes smaller, as the arrangement of the resistor departs from the power source. Thus, the charge of the surge current can be discharged to the GND side rapidly. Therefore, high voltage is not applied to the transistor disposed far from the power source, so that breakdown of the transistor is restricted, and breakdown of the whole circuit is also restricted.

Thus, the above device has high withstand voltage totally, which is required for the device, and circuit breakdown of the device is limited even when a voltage surge is inputted into the device.

Alternatively, a difference of resistance between the Ith step resistor and the (I+1)th step resistor may be constant. In this case, the charge of the surge current is not accumulated in a specific one resistor, so that the charge of the surge current is discharged to the GND side homogeneously. Accordingly, high voltage is not applied to a specific one transistor such as a transistor far from the power source, so that circuit breakdown is limited.

Further, a semiconductor device includes: a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two; an input terminal provided by a gate terminal of the first step transistor; a plurality of resistors, which are connected in series between the ground potential and the predetermined potential, wherein one of the resistors disposed on the utmost ground potential side is defined as a first step resistor, and another resistor disposed on the utmost predetermined potential side is defined as a Nth step resistor; an output terminal provided by a predetermined potential side terminal of the Nth step transistor; and a plurality of first capacitors. A gate terminal of each transistor other than the first step transistor is sequentially connected between neighboring two resistors, and each first capacitor is connected in parallel to each transistor.

In the above device, since the voltage between the GND potential and the predetermined potential is divided by N transistors, the required withstand voltage of each transistor is substantially reduced to one-Nth. Accordingly, the device has high withstand voltage as a whole.

Further, the first capacitor is connected in parallel to each transistor. N transistors are connected in series between the GND potential and the predetermined potential. Accordingly, the first capacitor connected in parallel to each transistor is substantially connected in series between the GND potential and the predetermined potential. Thus, a transmission passage of an alternating current is formed between the GND potential and the predetermined potential.

When the device is switched on or off, the transmission passage composed of the first capacitor functions as a bypass passage of the input signal pulse for transmitting a potential of the pulse. Specifically, when the input signal pulse starts to rise or when the input signal pulse starts to decay, the gate capacitor of each transistor can be charged up or discharged through the bypass passage. Accordingly, when the input signal pulse starts to rise or when the input signal pulse starts to decay, the signal change is rapidly transmitted to each transistor through the bypass passage. Thus, the device has an additional passage for charge and discharge of the gate capacitance so that a switching speed of the device is improved. Here, in a case where the device does not have the first capacitor connected in parallel to each transistor, the current flows into each transistor through a load resistor when the input signal pulse is inputted into the device. A potential drop of each transistor is transmitted so that an output signal is retrieved from the device. Thus, a delay caused by the on-state resistance of each transistor and each load resistor is generated so that a switching speed of the device may be reduced.

Furthermore, when the voltage surge is applied to the device, the charge of the surge current is rapidly discharged to the GND side through the transmission passage provided by the first capacitor. Accordingly, high voltage caused by the voltage surge is not applied to each transistor, so that circuit breakdown of the device is prevented.

Further, even when the device has a parasitic capacitance therein, the circuit breakdown of the device is restricted when the voltage surge is applied to the device. Specifically, by designing the capacitance of the first capacitor to be larger than the parasitic capacitance, the charge of the surge current is rapidly discharged to the GND side through the transmission passage of the alternating component, and the potential drop caused by the parasitic capacitance is cancelled so that the voltage applied to each transistor is equalized. Thus, the circuit breakdown caused by breakdown of the transistor is limited.

Thus, the above device has high withstand voltage totally, which is required for the device, and circuit breakdown of the device is limited even when a voltage surge is inputted into the device. Further, even when the above device has the parasitic capacitance, the circuit breakdown of the device is limited. Furthermore, even when a high voltage dividing resistance is added into the device, the device has sufficient switching speed.

Alternatively, each first capacitor may have a first capacitance in a range between 1 pF and 15 pF. This is because the following conditions are required for the device. In the above device, it is preferred that the capacitance of the first capacitor is larger than a normal parasitic capacitance. On the other hand, when the capacitance of the first capacitor is large, a current for charging the first capacitor is required, so that the switching speed may be reduced. Further, preferably, the first capacitor has the same withstand voltage as the transistor, since the first capacitor is connected in parallel to the transistor.

A semiconductor device includes: a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two; an input terminal provided by a gate terminal of the first step transistor; a plurality of parallel RC elements, which are connected in series between the ground potential and the predetermined potential, wherein each parallel RC element includes a resistor and a second capacitor, which are connected in parallel each other, and wherein one of the parallel RC elements disposed on the utmost ground potential side is defined as a first step parallel RC element, and another parallel RC element disposed on the utmost predetermined potential side is defined as a Nth step parallel RC element; and an output terminal provided by a predetermined potential side terminal of the Nth step transistor. A gate terminal of each transistor other than the first step transistor is sequentially connected between neighboring two parallel RC elements.

In the above device, since the voltage between the GND potential and the predetermined potential is divided by N transistors, the required withstand voltage of each transistor is substantially reduced to one-Nth. Accordingly, the device has high withstand voltage as a whole.

In the above device, a transmission passage provided by the second capacitor functions as a bypass passage of the input signal pulse for transmitting a potential of the pulse. Accordingly, when the input signal pulse starts to rise or when the input signal pulse starts to decay, the signal change is rapidly transmitted to each transistor through the bypass passage. Thus, the device has an additional passage for chare and discharge of the gate capacitance so that a switching speed of the device is improved.

Further, when the voltage surge is applied to the device, the charge of the surge current is rapidly discharged to the GND side through the transmission passage. Accordingly, high voltage caused by the voltage surge is not applied to each transistor, so that circuit breakdown of the device is prevented.

Furthermore, even when the device has a parasitic capacitance therein, the circuit breakdown of the device is restricted when the voltage surge is applied to the device. Specifically, by designing the capacitance of the second capacitor to be larger than the parasitic capacitance, the charge of the surge current is rapidly discharged to the GND side through the transmission passage of the alternating component, and the potential drop caused by the parasitic capacitance is cancelled so that the voltage applied to each transistor is equalized. Thus, the circuit breakdown caused by breakdown of the transistor is limited.

Thus, the above device has high withstand voltage totally, which is required for the device, and circuit breakdown of the device is limited even when a voltage surge is inputted into the device. Further, even when the above device has the parasitic capacitance, the circuit breakdown of the device is limited. Furthermore, even when a high voltage dividing resistance is added into the device, the device has sufficient switching speed.

Alternatively, the resistor in each parallel RC element may have a predetermined same resistance. One of the second capacitors in the parallel RC elements defined as an Ith step second capacitor has a capacitance, which is larger than a capacitance of a (I+1)th step second capacitor, and I is a given natural number in a range between one and (N-1). In the above device, since each resistor in the parallel RC elements has the same resistance, the same voltage is applied to each transistor when the device is operated in normal state. Thus, the voltage between the GND potential and the predetermined potential is divided by N transistors, so that the required withstand voltage of each transistor is substantially reduced to one-Nth. Accordingly, the device has high withstand voltage as a whole. Further, the capacitance of the second capacitor becomes larger as the position of the second capacitor is far from the power source side for providing the predetermined voltage. Thus, the charge is not prevented from accumulating in the second capacitor. Thus, the charge of the surge current can be discharged to the GND side rapidly. Accordingly, high voltage caused by the voltage surge is not applied to the transistor disposed far from the power source.

Alternatively, the Nth step second capacitor in the Nth step parallel RC element may have a capacitance substantially equal to a gate capacitance of the Nth step transistor, and a difference of capacitance between the Ith step second capacitor and the (I+1)th step second capacitor may be substantially equal to a gate capacitance of the Ith step transistor. In this case, the charge of the surge current is not accumulated in a gate of a specific one transistor and in a specific one second capacitor. Thus, the charge of the surge current is rapidly discharged to the GNBD side. Thus, high voltage caused by the voltage surge is not applied to the specific one transistor, so that circuit breakdown of the device is prevented.

Alternatively, the Nth second capacitor in the Nth step parallel RC element may have a predetermined capacitance, and a difference of capacitance between the Ith step second capacitor and the (I+1)th step second capacitor may be constant. In this case, the charge of the surge current is uniformly discharged to the GND side. Accordingly, even when each transistor has the same withstand voltage, breakdown of each transistor is prevented, so that circuit breakdown of the device is restricted.

Alternatively, each transistor may have a predetermined same withstand voltage. In this case, the voltage, i.e., the withstand voltage of each transistor is uniformed so that each withstand voltage of the transistors is minimized.

Alternatively, each second capacitor may have a second capacitance in a range between 1 pF and 15 pF. This is because the following conditions are required for the device. In the above device, it is preferred that the capacitance of the second capacitor is larger than a normal parasitic capacitance. On the other hand, when the capacitance of the second capacitor is large, a current for charging the second capacitor is required, so that the switching speed may be reduced. Further, preferably, the second capacitor has the same withstand voltage as the transistor.

Alternatively, the device may further include: a plurality of first capacitors. Each first capacitor is connected in parallel to each transistor. In the above device, two transmission passages provided by the second capacitor and the first capacitor function as a bypass passage of the input signal pulse for transmitting a potential of the pulse. Accordingly, when the input signal pulse starts to rise or when the input signal pulse starts to decay, the signal change is rapidly transmitted to each transistor through the bypass passage. Thus, the device has two additional passages for charge and discharge of the gate capacitance so that a switching speed of the device is much improved. Further, the circuit breakdown of the device is much prevented by discharging the charge of the surge current to the GND through two transmission passages.

Alternatively, each transistor may be disposed in a SOI layer of a SOI semiconductor substrate having an embedded oxide film, and the transistors may be insulated and separated each other by an insulation separation trench, which penetrates the SOI layer and reaches the embedded oxide film. Further, the insulation separation trench may include N-fold trench parts. The Nth step transistor may be surrounded by the N-fold trench parts. One of the transistors defined as an Ith step transistor may be surrounded by I-fold trench parts, and I is a given natural number in a range between one and (N-1). In this case, the voltage to be applied to each region surrounded with the insulation separation trench is equalized in accordance with a voltage increase from the GND potential to the predetermined potential. Thus, the voltage range of each transistor is gradually changed from the GND potential to the predetermined potential in sequential turn. Here, since only one trench part is disposed between neighboring two transistors, the wiring for the transistors is easily formed therebetween, and occupation area of the device is reduced so that the dimensions of the device are minimized.

Alternatively, the device may further include: a high impurity concentration layer having a same conductive type as the SOI layer. The high impurity concentration layer is disposed in the SOI layer. In this case, the transistor may have a normal withstand voltage, and it is not necessary to reduce the impurity concentration of the SOI layer for increasing the withstand voltage. Further, even when a voltage noise having a rapid change is generated around the device, expansion of a depletion layer from the embedded oxide film is reduced. Accordingly, malfunction caused by the voltage noise is prevented.

Alternatively, the device may further include: a plurality of first capacitors. Each first capacitor is connected in parallel to each transistor. At least one of the first capacitor and the second capacitor includes a dielectric layer and a pair of electrodes. The dielectric layer is provided by the insulation separation trench, and the electrodes are provided by the high impurity concentration layer, which is divided into two parts by the insulation separation trench. In this case, the first and the second capacitors can be formed at the same time, so that manufacturing cost of the device is reduced. Further, since the thick insulation separation trench functions as the dielectric layer, the withstand voltage of the capacitor can be secured to be equal to or larger than 100 V.

Alternatively, the device may further include: a plurality of first capacitors. Each first capacitor is connected in parallel to each transistor. At least one of the first capacitor and the second capacitor includes a dielectric layer and a pair of electrodes. The dielectric layer is provided by a sidewall oxide film disposed on a sidewall of the insulation separation trench. One of the electrodes is provided by a poly-silicon layer having conductivity embedded in the insulation separation trench through the sidewall oxide film, and the other one of the electrodes is provided by the high impurity concentration layer, which is disposed on a periphery of the insulation separation trench. In this case, the first and the second capacitors can be formed at the same time, so that manufacturing cost of the device is reduced. Further, since the thin sidewall oxide film functions as the dielectric layer, the capacitance of the capacitor can be easily increased.

Alternatively, the device may further include: a plurality of first capacitors. Each first capacitor is connected in parallel to each transistor. At least one of the first capacitor and the second capacitor includes a dielectric layer and a pair of electrodes. The dielectric layer is provided by an oxide layer disposed on the SOI layer. One of the electrodes is provided by a poly-silicon layer having conductivity disposed on the oxide layer on the SOI layer, and the other one of the electrodes is provided by the high impurity concentration layer, which is disposed in the SOI layer. In this case, the first and the second capacitors can be formed at the same time, so that manufacturing cost of the device is reduced.

Alternatively, the device may further include: a plurality of first capacitors. Each first capacitor is connected in parallel to each transistor. At least one of the first capacitor and the second capacitor includes a dielectric layer and a pair of electrodes The dielectric layer is provided by an interlayer insulation film disposed on an upper side of the SOI layer. One of the electrodes is provided by a poly-silicon layer having conductivity disposed on an oxide layer on the SOI layer, and the other one of the electrodes is provided by an aluminum layer or an aluminum alloy layer, which is disposed on the interlayer insulation film. Further, the dielectric layer may be provided by an interlayer insulation film disposed on an upper side of the SOI layer. One of the electrodes is provided by an aluminum layer or an aluminum alloy layer disposed on an oxide layer on the SOI layer, and the other one of the electrodes is provided by an aluminum layer or an aluminum alloy layer, which is disposed on the interlayer insulation film.

Alternatively, the device may be used for a level shift circuit in a high voltage IC. The high voltage IC is capable of driving an inverter. The high voltage IC includes: a ground reference gate driving circuit having a ground potential as a reference potential; a floating reference gate driving circuit having a floating potential as a reference potential; a control circuit for controlling the ground reference gate driving circuit and the floating reference gate driving circuit; and the level shift circuit for level-shifting an input/output signal of the control circuit between the ground potential and the floating potential. The floating potential is preliminarily determined, and the level shift circuit is disposed between the control circuit and the floating reference gate driving circuit. Further, the high voltage IC may be capable of driving the inverter for an in-vehicle motor. Further, the high voltage IC may be capable of driving the inverter for an in-vehicle air-conditioner.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two;
an input terminal provided by a gate terminal of the first step transistor;
a plurality of resistors, which are connected in series between the ground potential and the predetermined potential, wherein one of the resistors disposed on the utmost ground potential side is defined as a first step resistor, and another resistor disposed on the utmost predetermined potential side is defined as a Nth step resistor; and
an output terminal provided by a predetermined potential side terminal of the Nth step transistor, wherein
a gate terminal of each transistor other than the first step transistor is sequentially connected between neighboring two resistors,
one of the resistors defined as an Ith step resistor has a resistance, which is smaller than a resistance of a (I+1)th step resistor, and
I is a given natural number in a range between one and (N-1).

2. The device according to claim 1, wherein
a difference of resistance between the Ith step resistor and the (I+1)th step resistor is constant.

3. The device according to claim 1, wherein
each transistor is a MOS type transistor or an IGBT.

4. The device according to claim 1, wherein
each transistor is disposed in a SOI layer of a SOI semiconductor substrate having an embedded oxide film, and
the transistors are insulated and separated each other by an insulation separation trench, which penetrates the SOI layer and reaches the embedded oxide film.

5. The device according to claim 4, wherein
the insulation separation trench includes N-fold trench parts,
the Nth step transistor is surrounded by the N-fold trench parts,
one of the transistors defined as an Ith step transistor is surrounded by I-fold trench parts, and
I is a given natural number in a range between one and (N-1).

6. The device according to claim 4, further comprising:
a high impurity concentration layer having a same conductive type as the SOI layer, wherein
the high impurity concentration layer is disposed in the SOI layer.

7. The device according to claim 4, wherein
the SOI layer is a N conductive type.

8. The device according to claim 1, wherein
the resistor is made of poly-silicon film including an impurity or Cr—Si metallic film.

9. The device according to claim 1, wherein
the device is used for a level shift circuit in a high voltage IC,
the high voltage IC is capable of driving an inverter,
the high voltage IC includes:
a ground reference gate driving circuit having a ground potential as a reference potential;
a floating reference gate driving circuit having a floating potential as a reference potential;
a control circuit for controlling the ground reference gate driving circuit and the floating reference gate driving circuit; and
the level shift circuit for level-shifting an input/output signal of the control circuit between the ground potential and the floating potential,
the floating potential is preliminarily determined, and
the level shift circuit is disposed between the control circuit and the floating reference gate driving circuit.

10. The device according to claim 9, wherein
the high voltage IC is capable of driving the inverter for an in-vehicle motor.

11. The device according to claim 9, wherein
the high voltage IC is capable of driving the inverter for an in-vehicle air-conditioner.

12. A semiconductor device comprising:
a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two;
an input terminal provided by a gate terminal of the first step transistor;
a plurality of resistors, which are connected in series between the ground potential and the predetermined potential, wherein one of the resistors disposed on the utmost ground potential side is defined as a first step resistor, and another resistor disposed on the utmost predetermined potential side is defined as a Nth step resistor;
an output terminal provided by a predetermined potential side terminal of the Nth step transistor; and
a plurality of first capacitors, wherein
a gate terminal of each transistor other than the first step transistor is sequentially connected between neighboring two resistors, and
each first capacitor is connected in parallel to each transistor.

13. The device according to claim 12, wherein
each first capacitor has a first capacitance in a range between 1 pF and 15 pF.

14. The device according to claim 12, wherein
each transistor is a MOS type transistor or an IGBT.

15. The device according to claim 12, wherein
each transistor is disposed in a SOI layer of a SOI semiconductor substrate having an embedded oxide film, and
the transistors are insulated and separated each other by an insulation separation trench, which penetrates the SOI layer and reaches the embedded oxide film.

16. The device according to claim 15, wherein
the insulation separation trench includes N-fold trench parts,
the Nth step transistor is surrounded by the N-fold trench parts,
one of the transistors defined as an Ith step transistor is surrounded by I-fold trench parts, and
I is a given natural number in a range between one and (N-1).

17. The device according to claim 15, further comprising:
a high impurity concentration layer having a same conductive type as the SOI layer, wherein
the high impurity concentration layer is disposed in the SOI layer.

18. The device according to claim 15, wherein
the SOI layer is a N conductive type.

19. The device according to claim 17, wherein
the first capacitor includes a dielectric layer and a pair of electrodes,
the dielectric layer is provided by the insulation separation trench, and
the electrodes are provided by the high impurity concentration layer, which is divided into two parts by the insulation separation trench.

20. The device according to claim 17, wherein
the first capacitor includes a dielectric layer and a pair of electrodes,
the dielectric layer is provided by a sidewall oxide film disposed on a sidewall of the insulation separation trench,
one of the electrodes is provided by a poly-silicon layer having conductivity embedded in the insulation separation trench through the sidewall oxide film, and
the other one of the electrodes is provided by the high impurity concentration layer, which is disposed on a periphery of the insulation separation trench.

21. The device according to claim 17, wherein
the first capacitor includes a dielectric layer and a pair of electrodes,
the dielectric layer is provided by an oxide layer disposed on the SOI layer,
one of the electrodes is provided by a poly-silicon layer having conductivity disposed on the oxide layer on the SOI layer, and
the other one of the electrodes is provided by the high impurity concentration layer, which is disposed in the SOI layer.

22. The device according to claim 17, wherein
the first capacitor includes a dielectric layer and a pair of electrodes,
the dielectric layer is provided by an interlayer insulation film disposed on an upper side of the SOI layer,
one of the electrodes is provided by a poly-silicon layer having conductivity disposed on an oxide layer on the SOI layer, and
the other one of the electrodes is provided by an aluminum layer or an aluminum alloy layer, which is disposed on the interlayer insulation film.

23. The device according to claim 17, wherein
the first capacitor includes a dielectric layer and a pair of electrodes,
the dielectric layer is provided by an interlayer insulation film disposed on an upper side of the SOI layer,
one of the electrodes is provided by an aluminum layer or an aluminum alloy layer disposed on an oxide layer on the SOI layer, and
the other one of the electrodes is provided by an aluminum layer or an aluminum alloy layer, which is disposed on the interlayer insulation film.

24. The device according to claim 12, wherein
the resistor is made of poly-silicon film including an impurity or Cr—Si metallic film.

25. The device according to claim 12, wherein
the device is used for a level shift circuit in a high voltage IC,
the high voltage IC is capable of driving an inverter,
the high voltage IC includes:
a ground reference gate driving circuit having a ground potential as a reference potential;
a floating reference gate driving circuit having a floating potential as a reference potential;
a control circuit for controlling the ground reference gate driving circuit and the floating reference gate driving circuit; and
the level shift circuit for level-shifting an input/output signal of the control circuit between the ground potential and the floating potential,
the floating potential is preliminarily determined, and
the level shift circuit is disposed between the control circuit and the floating reference gate driving circuit.

26. The device according to claim 25, wherein
the high voltage IC is capable of driving the inverter for an in-vehicle motor.

27. The device according to claim 25, wherein
the high voltage IC is capable of driving the inverter for an in-vehicle air-conditioner.

28. A semiconductor device comprising:
a plurality of transistors, which are insulated and separated each other, wherein the transistors are connected in series between a ground potential and a predetermined potential, wherein one of the transistors disposed on an utmost ground potential side is defined as a first step transistor, and another transistor disposed on an utmost predetermined potential side is defined as a Nth step transistor, and wherein N is a predetermined natural number equal to or larger than two;
an input terminal provided by a gate terminal of the first step transistor;
a plurality of parallel RC elements, which are connected in series between the ground potential and the predetermined potential, wherein each parallel RC element includes a resistor and a second capacitor, which are connected in parallel each other, and wherein one of the parallel RC elements disposed on the utmost ground potential side is defined as a first step parallel RC element, and another parallel RC element disposed on the utmost predetermined potential side is defined as a Nth step parallel RC element; and
an output terminal provided by a predetermined potential side terminal of the Nth step transistor, wherein
a gate terminal of each transistor other than the first step transistor is sequentially connected between neighboring two parallel RC elements.

29. The device according to claim 28, wherein
the resistor in each parallel RC element has a predetermined same resistance,
one of the second capacitors in the parallel RC elements defined as an Ith step second capacitor has a capacitance, which is larger than a capacitance of a (I+1)th step second capacitor, and
I is a given natural number in a range between one and (N-1).

30. The device according to claim 29, wherein
the Nth step second capacitor in the Nth step parallel RC element has a capacitance substantially equal to a gate capacitance of the Nth step transistor, and
a difference of capacitance between the Ith step second capacitor and the (I+1)th step second capacitor is substantially equal to a gate capacitance of the Ith step transistor.

31. The device according to claim 30, wherein
the Nth second capacitor in the Nth step parallel RC element has a predetermined capacitance, and
a difference of capacitance between the Ith step second capacitor and the (I+1)th step second capacitor is constant.

32. The device according to claim 29, wherein
each transistor has a predetermined same withstand voltage.

33. The device according to claim 28, wherein
each second capacitor has a second capacitance in a range between 1 pF and 15 pF.

34. The device according to claim 28, further comprising:
a plurality of first capacitors, wherein
each first capacitor is connected in parallel to each transistor.

35. The device according to claim 34, wherein
each first capacitor has a first capacitance in a range between 1 pF and 15 pF.

36. The device according to claim 28, wherein
each transistor is a MOS type transistor or an IGBT.

37. The device according to claim 28, wherein
each transistor is disposed in a SOI layer of a SOI semiconductor substrate having an embedded oxide film, and
the transistors are insulated and separated each other by an insulation separation trench, which penetrates the SOI layer and reaches the embedded oxide film.

38. The device according to claim 37, wherein
the insulation separation trench includes N-fold trench parts,
the Nth step transistor is surrounded by the N-fold trench parts,
one of the transistors defined as an Ith step transistor is surrounded by I-fold trench parts, and
I is a given natural number in a range between one and (N-1).

39. The device according to claim 37, further comprising:
a high impurity concentration layer having a same conductive type as the SOI layer, wherein
the high impurity concentration layer is disposed in the SOI layer.

40. The device according to claim 37, wherein
the SOI layer is a N conductive type.

41. The device according to claim 39, further comprising:
a plurality of first capacitors, wherein
each first capacitor is connected in parallel to each transistor,
at least one of the first capacitor and the second capacitor includes a dielectric layer and a pair of electrodes,
the dielectric layer is provided by the insulation separation trench, and
the electrodes are provided by the high impurity concentration layer, which is divided into two parts by the insulation separation trench.

42. The device according to claim 39, further comprising:
a plurality of first capacitors, wherein
each first capacitor is connected in parallel to each transistor,
at least one of the first capacitor and the second capacitor includes a dielectric layer and a pair of electrodes,
the dielectric layer is provided by a sidewall oxide film disposed on a sidewall of the insulation separation trench,
one of the electrodes is provided by a poly-silicon layer having conductivity embedded in the insulation separation trench through the sidewall oxide film, and
the other one of the electrodes is provided by the high impurity concentration layer, which is disposed on a periphery of the insulation separation trench.

43. The device according to claim 39, further comprising:
a plurality of first capacitors, wherein
each first capacitor is connected in parallel to each transistor,
at least one of the first capacitor and the second capacitor includes a dielectric layer and a pair of electrodes,
the dielectric layer is provided by an oxide layer disposed on the SOI layer,
one of the electrodes is provided by a poly-silicon layer having conductivity disposed on the oxide layer on the SOI layer, and
the other one of the electrodes is provided by the high impurity concentration layer, which is disposed in the SOI layer.

44. The device according to claim 39, further comprising:
a plurality of first capacitors, wherein
each first capacitor is connected in parallel to each transistor,
at least one of the first capacitor and the second capacitor includes a dielectric layer and a pair of electrodes,
the dielectric layer is provided by an interlayer insulation film disposed on an upper side of the SOI layer,
one of the electrodes is provided by a poly-silicon layer having conductivity disposed on an oxide layer on the SOI layer, and
the other one of the electrodes is provided by an aluminum layer or an aluminum alloy layer, which is disposed on the interlayer insulation film.

45. The device according to claim 39,further comprising:
a plurality of first capacitors, wherein
each first capacitor is connected in parallel to each transistor,
at least one of the first capacitor and the second capacitor includes a dielectric layer and a pair of electrodes,
the dielectric layer is provided by an interlayer insulation film disposed on an upper side of the SOI layer,
one of the electrodes is provided by an aluminum layer or an aluminum alloy layer disposed on an oxide layer on the SOI layer, and
the other one of the electrodes is provided by an aluminum layer or an aluminum alloy layer, which is disposed on the interlayer insulation film.

46. The device according to claim 28, wherein
the resistor is made of poly-silicon film including an impurity or Cr—Si metallic film.

47. The device according to claim 28, wherein
the device is used for a level shift circuit in a high voltage IC,
the high voltage IC is capable of driving an inverter,
the high voltage IC includes:
a ground reference gate driving circuit having a ground potential as a reference potential;
a floating reference gate driving circuit having a floating potential as a reference potential;
a control circuit for controlling the ground reference gate driving circuit and the floating reference gate driving circuit; and
the level shift circuit for level-shifting an input/output signal of the control circuit between the ground potential and the floating potential,
the floating potential is preliminarily determined, and
the level shift circuit is disposed between the control circuit and the floating reference gate driving circuit.

48. The device according to claim 47, wherein
the high voltage IC is capable of driving the inverter for an in-vehicle motor.

49. The device according to claim 47, wherein
the high voltage IC is capable of driving the inverter for an in-vehicle air-conditioner.
